(19) United States
(12) Patent Application Publication
(10) Pub. No.: US 2025/0338725 A1
(43) Pub. Date: Oct. 30, 2025

(54) DISPLAY PANEL AND DISPLAY DEVICE

(71) Applicants: Hefei Visionox Technology Co., Ltd., Hefei (CN); VISIONOX TECHNOLOGY INC., Kunshan (CN)

(72) Inventors: Zhiwei ZHOU, Hefei (CN); Jinfang ZHANG, Hefei (CN); Lu ZHANG, Hefei (CN); Yuan YAO, Hefei (CN); Ying SHEN, Hefei (CN)

(73) Assignees: Hefei Visionox Technology Co., Ltd., Hefei (CN); VISIONOX TECHNOLOGY INC., Kunshan (CN)

(21) Appl. No.: 19/192,906

(22) Filed: Apr. 29, 2025

(30) Foreign Application Priority Data
Apr. 30, 2024 (CN) 202410545864.5
Aug. 23, 2024 (CN) 202411166874.4

(51) Int. Cl. H10K 59/122; H10K 59/40

(52) U.S. Cl. CPC H10K 59/122; H10K 59/40

(57) ABSTRACT

A display panel includes a baseplate, an isolation structure layer, and a light-emitting functional layer. The isolation structure layer is disposed on a side of the baseplate and includes an isolation structure and first defining openings formed by enclosure of the isolation structure, where the isolation structure includes an isolation portion located between two adjacent defining openings, and the isolation portion includes a light-shielding portion. The light-emitting functional layer includes a first electrode, a light-emitting unit and a second electrode that are at least partially located in a first defining opening and are sequentially stacked in a direction away from the baseplate, and at least a portion of each of the first electrode, the light-emitting unit and the second electrode is configured to constitute a sub-pixel. At least one first defining opening includes a first opening region and a second opening region.

### CROSS-REFERENCE TO RELATED APPLICATION(S)

This application claims the priority of a Chinese Patent Application No. 202411166874.4, filed on Aug. 23, 2024, and the priority of a Chinese Patent Application No. 202410545864.5, filed on Apr. 30, 2024, the disclosures of which are incorporated herein by reference in their entireties.

### TECHNICAL FIELD

The present application belongs to the field of display technology and, in particular, relates to a display panel and a display device.

### BACKGROUND

An organic light-emitting diode (OLED) and a flat panel display device based on technologies such as a light-emitting diode (LED) are widely used in various consumer electronic products such as a mobile phone, a television, a notebook computer and a desktop computer due to advantages such as high image quality, power saving, a thin body and a wide application range, thereby becoming mainstreams among display devices.

However, the performance of the current OLED display product needs to be improved.

### SUMMARY

Embodiments of the present application provide a display panel and a display device.

Embodiments in a first aspect of the present application provide a display panel. The display panel includes a baseplate, an isolation structure layer and a light-emitting functional layer. The isolation structure layer is disposed on a side of the baseplate and includes an isolation structure and one or more first defining openings formed by the enclosure of the isolation structure, where the isolation structure includes an isolation portion located between two adjacent first defining openings among the first defining openings, where the isolation portion includes a light-shielding portion. The light-emitting functional layer includes one or more first electrodes, one or more light-emitting units and one or more second electrodes, where a light-emitting unit and a second electrode are at least partially located in a first defining opening among the first defining openings and are sequentially stacked in a direction away from the baseplate, and at least a portion of the first electrodes, a portion of the light-emitting units and a portion of the second electrodes are configured to constitute one or more sub-pixels. At least one first defining opening among the first defining openings includes one or more first opening regions and one or more second opening regions, where an orthographic projection of the first electrode on the baseplate coincides with an orthographic projection of the first opening region on the baseplate, a light-transmissive gap is formed between the orthographic projection of the first electrode on the baseplate and an orthographic projection of an edge of a light-shielding portion of a corresponding isolation portion on the baseplate, and an orthographic projection of the second opening region on the baseplate is located within an orthographic projection of the light-transmissive gap on the baseplate.

Embodiments in the first aspect of the present application further provide a display panel. The display panel includes a baseplate, an isolation structure disposed on a side of the baseplate and enclosing to form one or more first opening regions and one or more sub-pixels, a sub-pixel is at least partially located in a first opening region, where one or more second opening regions communicated with the first opening region are disposed on a side of at least a portion of the isolation structure facing an isolation opening, and the one or more second opening regions pass through the isolation structure along a thickness direction of the display panel.

Embodiments in a second aspect of the present application provide a display device. The display device includes the display panel in any one of the preceding embodiments.

The display panel provided in the embodiments of the present application includes the baseplate, the isolation structure layer, and the light-emitting functional layer. The isolation structure layer is disposed on the side of the baseplate and includes the isolation structure. The isolation structure encloses to form the first defining openings. The first defining openings are used for accommodating the sub-pixels to improve the problem of light emission interference between different sub-pixels. The light-emitting functional layer includes the first electrodes, the light-emitting units and the second electrodes. The first electrode and the second electrode are used for driving the light-emitting unit to emit light, thereby achieving the light-emitting display of the sub-pixel. The at least one first defining opening includes the first opening region and the second opening region that are communicated with each other. The orthographic projection of the first electrode on the baseplate coincides with the orthographic projection of the first opening region on the baseplate. The first opening region is used for achieving the light emission of the display panel. The light-transmissive gap located in the first defining opening is formed between the orthographic projection of the first electrode on the baseplate and the orthographic projection of the edge of the light-shielding portion of the corresponding isolation portion on the baseplate. The orthographic projection of the second opening region on the baseplate is located within the orthographic projection of the light-transmissive gap on the baseplate, that is, the second opening region is used for achieving the light transmission of the display panel.

### BRIEF DESCRIPTION OF DRAWINGS

To illustrate technical solutions in embodiments of the present application more clearly, the drawings used in description of the embodiments will be briefly described below. Apparently, the drawings described below illustrate part of the embodiments of the present application, and those of ordinary skill in the art may obtain other drawings based on the drawings described below on the premise that no creative work is done.

FIG. 1 is a partial structure diagram of a display panel according to one or more embodiments of the present application.

FIG. 2 is a structure diagram of FIG. 1 taken along a B-B section in an example.

FIG. 3 is a structure diagram of FIG. 1 taken along an A-A section in an example.

FIG. 4 is a partially enlarged structure diagram of a display panel according to one or more embodiments of the present application.

FIG. 5 is a structure diagram of FIG. 1 taken along an A-A section in another example.

FIG. 6 is a structure diagram of FIG. 1 taken along an A-A section in another example.

FIG. 7 is a structure diagram of FIG. 1 taken along a B-B section in another example.

FIG. 8 is a structure diagram of FIG. 1 taken along an A-A section in another example.

FIG. 9 is a structure diagram of FIG. 1 taken along a B-B section in another example.

FIG. 10 is a partial structure diagram of a display panel according to another embodiment of the present application.

FIG. 11 is a structure diagram of FIG. 1 taken along an A-A section in another example.

FIG. 12 is a structure diagram of FIG. 1 taken along an A-A section in another example.

FIG. 13 is a partial structure diagram of a display panel according to another embodiment of the present application.

FIG. 14 is a partial structure diagram of a display panel according to another embodiment of the present application.

FIG. 15 is a partial structure diagram of a display panel according to another embodiment of the present application.

FIG. 16 is a partial structure diagram of a display panel according to another embodiment of the present application.

FIG. 17 is a structure diagram of FIG. 1 taken along an A-A section in another example.

FIG. 18 is a structure diagram of FIG. 1 taken along an A-A section in another example.

### REFERENCE LIST

10 display panel
100 baseplate
110 substrate
120 first insulating layer
130 second insulating layer
140 third insulating layer
150 driver circuit
151 transistor
151a gate
151b source and drain
152 storage capacitor
152a first plate
152b second plate
160 planarization layer
161 connecting hole
200 pixel defining portion
210 pixel opening
211 first opening
212 second opening
213 third opening
220 accommodation recess
230 defining layer opening
300 isolation structure
300a isolation portion
300b light-shielding portion
310 first defining opening
310a first type of defining opening
310b second type of defining opening
310c third type of defining opening
311 first opening region
312 second opening region
312a first type of light-transmissive region
312b second type of light-transmissive region
320 first isolation segment
330 second isolation segment
340 third defining opening
30a first light-transmissive region
30b second light-transmissive region
301 first isolation portion
302 second isolation portion
303 third isolation portion
40 light-emitting functional layer
400 sub-pixel
400a first type of sub-pixel
400b second type of sub-pixel
400c third type of sub-pixel
410 first electrode
411 connection portion
412 second conductive layer
420 light-emitting unit
421 second hollowed-out opening
430 second electrode
431 third hollowed-out opening
500 encapsulation layer
510 first encapsulation layer
511 first encapsulation portion
520 second encapsulation layer
530 third encapsulation layer
600 touch electrode
700 light-filtering layer
710 light-shielding defining portion
720 second defining opening
721 third opening region
722 fourth opening region
730 light-filtering unit
X thickness direction
Y first direction
Z second direction
AA1 first display region
AA2 second display region
TG light-transmissive gap
C1 first pixel column
C2 second pixel column
R1 first pixel row
R2 second pixel row
G1 first spacing
G2 second spacing
G3 third spacing

### DETAILED DESCRIPTION

Features and example embodiments in various aspects of the present application are described below in detail. To provide a clearer understanding of the objects, technical solutions, and advantages of the present application, the present application is further described below in detail in conjunction with drawings and embodiments. It is to be understood that the embodiments described here are only configured to illustrate and not to limit the present application. For those skilled in the art, the present application may be implemented without some of these specific details. The following description of the embodiments is intended to provide a better understanding of the present application through examples of the present application.

It is to be noted that relationship terms such as first and second used herein, are used only for distinguishing one entity or operation from another and do not necessarily require or imply any such actual relationship or order between these entities or operations. Furthermore, the term “comprising”, “including”, or any other variant thereof is intended to encompass a non-exclusive inclusion so that a process, method, article, or device that includes a series of elements not only includes the expressly listed elements but also includes other elements that are not expressly listed or are inherent to such a process, method, article, or device. In the absence of more restrictions, the elements defined by the statement “including . . . ” do not exclude the presence of additional identical elements in the process, method, article, or device that includes the elements.

It is to be understood that when the structure of a component is described and a layer or region is referred to as “on” or “above” another layer or region, it may refer that the layer or region is directly located on another layer or region, or other layers or regions are included between the layer or region and another layer or region. If the component is turned over, the layer or region is located “below” or “underneath” another layer or region.

To better understand the present application, a display panel 10 and a display device in embodiments of the present application are described below in detail with reference to drawings.

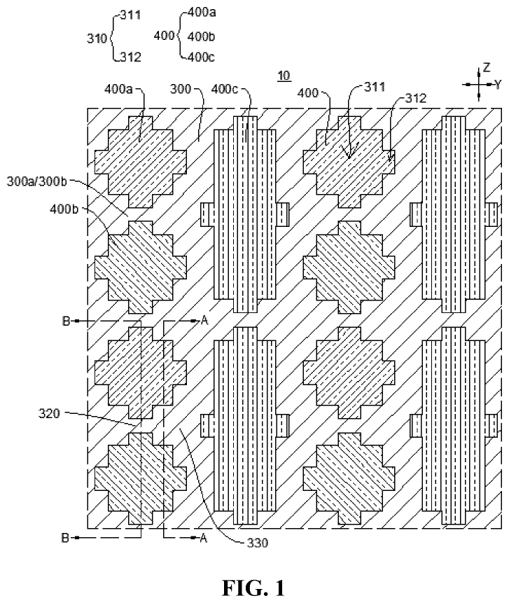

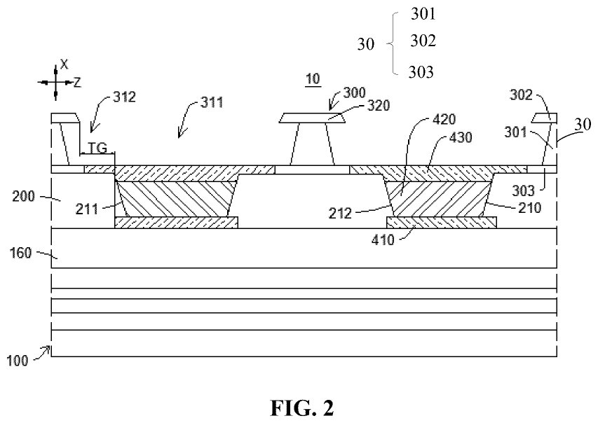

FIG. 1 is a partial structure diagram of a display panel 10 according to one or more embodiments of the present application. FIG. 2 is a structure diagram of FIG. 1 taken along a B-B section. FIG. 3 is a structure diagram of FIG. 1 taken along an A-A section. An X direction in the figure is a thickness direction X of the display panel 10, a Y direction in the figure is a first direction Y, and a Z direction in the figure is a second direction Z. The first direction Y, the second direction Z and the thickness direction X intersect each other. Optionally, the first direction Y, the second direction Z and the thickness direction X may be perpendicular to each other.

As shown in FIGS. 1 to 3, embodiments in a first aspect of the present application provide a display panel 10. The display panel 10 includes a baseplate 100, an isolation structure layer 30 and a light-emitting functional layer 40. The isolation structure layer 30 is disposed on a side of the baseplate 100 and includes an isolation structure 300 and one or more first defining openings 310 formed by the enclosure of the isolation structure 300, where the isolation structure 300 includes an isolation portion 300a located between two adjacent first defining openings, where the isolation portion 300a includes a light-shielding portion 300b. The light-emitting functional layer 40 includes one or more first electrodes 410, one or more light-emitting units 420 and one or more second electrode 430, where the light-emitting unit 420 and the second electrode 430 are at least partially located in the first defining opening 310 and are sequentially stacked in a direction facing away from the baseplate 100, and at least a portion of each of the first electrode 410, the light-emitting unit 420 and the second electrode 430 is configured to form a sub-pixel 400. At least one first defining opening 310 includes one or more first opening regions 311 and one or more second opening regions 312, where an orthographic projection of the first electrode 410 on the baseplate 100 coincides with an orthographic projection of the first opening region 311 on the baseplate 100, a light-transmissive gap TG is formed between the orthographic projection of the first electrode 410 on the baseplate 100 and an orthographic projection of an edge of a light-shielding portion 300b of a corresponding isolation portion 300a on the baseplate 100, and an orthographic projection of the second opening region on the baseplate 100 is located within an orthographic projection of the light-transmissive gap TG on the baseplate 100.

The display panel 10 provided in the embodiments of the present application includes the baseplate 100, the isolation structure layer 30 and the light-emitting functional layer 40. The isolation structure layer is disposed on the side of the baseplate 100 and includes the isolation structure 300. The isolation structure 300 encloses to form the first defining openings 310. The first defining opening 310 is used for accommodating the sub-pixel 400 to improve the problem of light emission interference between different sub-pixels 400. The light-emitting functional layer 40 includes the first electrode 410, the light-emitting unit 420 and the second electrode 430. The first electrode 410 and the second electrode 430 are used for driving the light-emitting unit 420 to emit light, thereby achieving the light-emitting display of the sub-pixel 400. At least one first defining opening 310 includes the first opening region 311 and the second opening region 312 that are connected to each other. The orthographic projection of the first electrode 410 on the baseplate 100 coincides with the orthographic projection of the first opening region 311 on the baseplate 100. The first opening region 311 is used for achieving the light emission of the display panel 10. The light-transmissive gap TG located in the first defining opening 310 is formed between the orthographic projection of the first electrode 410 on the baseplate 100 and the orthographic projection of the edge of the light-shielding portion 300b of the corresponding isolation portion 300a on the baseplate 100. The orthographic projection of the second opening region 312 on the baseplate 100 is located within the orthographic projection of the light-transmissive gap TG on the baseplate 100, that is, the second opening region 312 is used for achieving the light transmission of the display panel 10.

In the implementation of the present application, the first opening region 311 for achieving the light emission and the second opening region 312 for achieving the light transmission are communicated with each other so that in the thickness direction X of the display panel 10, light can better penetrate the display panel 10 in the second opening region 312, thereby better improving the light transmission of the display panel 10. Compared with a solution of alternately disposing a light-transmissive opening and an isolation opening, a distribution area of the light-shielding portion 300b between adjacent sub-pixels 400 can be reduced by about half by arranging the second opening region 312 and the first opening region 311 being communicated with each other, thereby effectively increasing a distribution area of a light-transmissive region and improving a transmittance and aperture ratio of the display panel.

The first opening region 311 in the present application may be an isolation opening in a priority application, and the second opening region 312 in the present application is a light-transmissive groove in the priority application (Application No. CN202410545864.5).

The sub-pixel 400 in the present application refers to a region on the light-emitting functional layer 40 that can emit light. For example, the display panel 10 further includes a pixel defining layer, where the pixel defining layer includes a pixel defining portion 200 and pixel openings 210 formed by enclosure of the pixel defining portion 200. The first electrode 410 is exposed by a corresponding pixel opening 210. The light-emitting unit 420 is at least partially located in the corresponding pixel opening 210. The second electrode 430 is located on a side of the light-emitting unit 420 facing away from the baseplate 100. The first electrode 410, the light-emitting unit 420 and the second electrode 430 corresponding to a region where the pixel opening 210 is located form a sub-pixel 400.

Optionally, one first defining opening 310 can correspond to one or more pixel openings 210. For example, an orthographic projection of one pixel opening 210 on the baseplate 100 is located within an orthographic projection of one first defining opening 310 on the baseplate 100, or orthographic projections of two or more pixel openings 210 on the baseplate 100 are located within the orthographic projection of the same first defining opening 310 on the baseplate 100.

The isolation structure layer 30 includes the isolation structure 300 and the first defining openings 310. Optionally, the isolation structure 300 is grid-shaped, and the isolation portion 300a is a certain segment of isolation structure 300 located between two adjacent first defining openings 310. The light-shielding portion 300b is a light-proof sublayer in the isolation portion 300a. The light-transmissive gap TG is located between an edge of the orthographic projection of the first electrode 410 on the baseplate 100 and an orthographic projection of an edge of the isolation portion 300a on the baseplate 100, where the edge of the isolation portion 300a faces the first defining opening 310 for accommodating the first electrode 410. That is, a distribution area of the first defining opening 310 is greater than a distribution area of the first electrode 410 correspondingly located in the first defining opening 310, thereby forming the light-transmissive gap TG between the first electrode 410 and the edge of the isolation portion 300a facing the first defining opening 310. The second opening region 312 is correspondingly located in the light-transmissive gap TG.

In some other optional embodiments, an orthographic projection of a pixel opening 210 on the baseplate 100 is located within an orthographic projection of a first defining opening 310 on the baseplate 100. Optionally, a region formed by the misalignment of the orthographic projection of the first defining opening 310 on the baseplate 100 with the orthographic projection of the pixel opening 210 on the baseplate 100 is the light-transmissive region, and a second opening region 312 is located in the light-transmissive region. The second opening region 312 may coincide with the light-transmissive region or may be located in the light-transmissive region, that is, the light-transmissive region is slightly greater than the second opening region 312. A region that coincides with the orthographic projection of the pixel opening 210 on the baseplate 100 is a region where the first opening region 311 is located.

In some embodiments of the present application, the first opening region 311 is communicated with the second opening region 312, and the second opening region 312 can be formed through the sinking of a surface on a side of the isolation structure 300 facing the first opening region 311, that is, the second opening region 312 can be formed relative to the sinking of a wall surface on the isolation structure 300 that participates in enclosing to form the first opening region 311. Optionally, a shape of the second opening region 312 is set in multiple manners. For example, a shape of the orthographic projection of the second opening region 312 on the baseplate 100 may be polygonal or an arc such as a semicircle or a semi-ellipse and is not specifically limited in the present application. The orthographic projection of the second opening region 312 on the baseplate 100 may refer to a projection region formed by the enclosure of an orthographic projection of an inner wall surface of the second opening region 312 on the baseplate 100 as mentioned above. The orthographic projection of the second opening region 312 on the baseplate 100 may also refer to a region where an orthographic projection of a hollowed-out portion on the baseplate 100 is located or a region formed through the misalignment with the orthographic projection of the pixel opening 210 on the baseplate 100 in the defining opening.

Optionally, multiple first defining openings 310 and multiple sub-pixels 400 may be disposed, and each first defining opening 310 may correspond to one sub-pixel 400. The isolation structure 300 may be in a mesh shape, and the first defining openings 310 may form in a hollowed-out region of the mesh-shaped isolation structure 300.

In some optional embodiments, in the direction facing away from the baseplate 100, the sub-pixel 400 may include the first electrode 410, the light-emitting unit 420 and the second electrode 430 that are stacked in sequence. The light-emitting functional layer 40 may include the first electrode 410, the light-emitting unit 420 and the second electrode 430 that are stacked in sequence, and a region corresponding to the pixel opening 210 on the first electrode 410, the light-emitting unit 420 and the second electrode 430 forms a sub-pixel 400. The light-emitting unit 420 may be a light-emitting layer in the priority case.

Optionally, the light-emitting unit 420 may include a hole injection layer (HIL), a hole transport layer (HTL), an electron injection layer (EIL) and an electron transport layer (ETL).

Optionally, the first electrode 410 and the second electrode 430 may be used as pixel electrodes of the display panel 10, one of the first electrode 410 and the second electrode 430 may be used as an anode, and the other may be used as a cathode to drive the light-emitting unit 420 to emit light. In the embodiments of the present application, the first electrode 410 as the anode of the display panel 10 and the second electrode 430 as the cathode of the display panel 10 are used as an example for description.

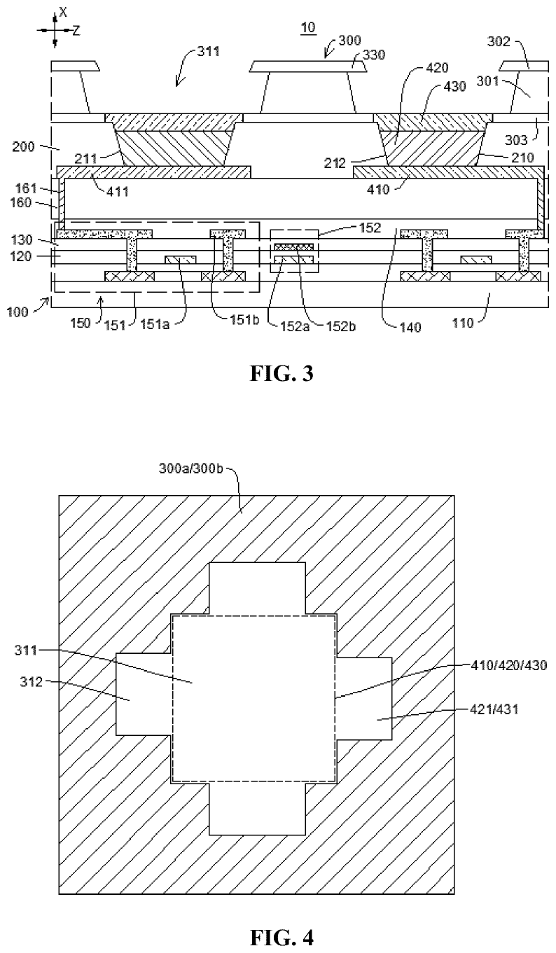

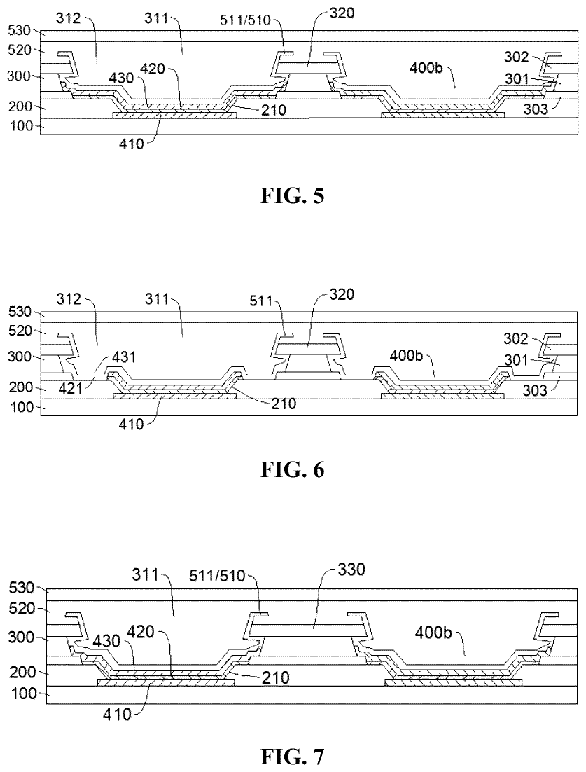

In some optional embodiments, as shown in FIGS. 4 and 5, the light-emitting unit 420 includes a light-transmissive material layer to enhance the transmittance of the display panel 10. Alternatively, as shown in FIGS. 4, 6 and 7, the light-emitting unit 420 is provided with one or more second hollowed-out openings 421 passing through the light-emitting unit 420, and an orthographic projection of the second hollowed-out opening 421 on the baseplate 100 at least partially overlaps the orthographic projection of the light-transmissive gap TG on the baseplate 100. The second hollowed-out opening 421 is disposed on the light-emitting unit 420 and is disposed in correspondence to the light-transmissive gap TG, thereby further improving a transmittance of the light-transmissive gap TG and improving the transmittance of the display panel 10.

Optionally, the orthographic projection of the second hollowed-out opening 421 on the baseplate 100 at least partially overlaps the orthographic projection of the second opening region 312 on the baseplate 100 to further improve a transmittance of the second opening region 312.

In some optional embodiments, as shown in FIGS. 4 and 5, the second electrode 430 includes a light-transmissive material layer to enhance the transmittance of the display panel 10. Alternatively, as shown in FIGS. 4, 6 and 7, the second electrode 430 is provided with one or more third hollowed-out openings 431 passing through the second electrode 430, and an orthographic projection of the third hollowed-out opening 431 on the baseplate 100 at least partially overlaps the orthographic projection of the light-transmissive gap TG on the baseplate 100. The third hollowed-out opening 431 is disposed on the second electrode 430 and is disposed in correspondence to the light-transmissive gap TG, thereby further improving the transmittance of the light-transmissive gap TG and improving the transmittance of the display panel 10.

As shown in FIGS. 6 and 7, a portion of second electrodes 430 in the display panel are each provided with a third hollowed-out opening 431, and the edges of the portion of second electrodes 430 at the third hollowed-out opening 431 are spaced apart from the isolation structure 300. The other portion of the second electrodes 430 are not provided with a third hollowed-out opening 431, and the other portion of the second electrodes 430 can be in direct contact with and connected to the isolation structure 300. Optionally, multiple third hollowed-out openings 431 are spaced around a center of a second electrode 430.

Optionally, the orthographic projection of the third hollowed-out opening 431 on the baseplate 100 at least partially overlaps the orthographic projection of the second opening region 312 on the baseplate 100 to further improve the transmittance of the second opening region 312.

In some optional embodiments, as shown in FIGS. 5 to 7, the display panel 10 includes an encapsulation layer 500 disposed on a side of the isolation structure 300 facing away from the baseplate 100 and a side of the sub-pixel 400 facing away from the baseplate 100, and the encapsulation layer 500 can be used for encapsulating the sub-pixel 400.

Optionally, the encapsulation layer 500 may include a first encapsulation layer 510 disposed on the side of the isolation structure 300 facing away from the baseplate 100 and the side of the sub-pixel 400 facing away from the baseplate 100, that is, the display panel 10 further includes a first encapsulation layer 510 located on a side of the second electrode 430 facing away from the baseplate 100. A material of the first encapsulation layer 510 may include an inorganic material so that the first encapsulation layer 510 can have a relatively good encapsulation ability to reduce an effect of vapors on the sub-pixel 400. Optionally, the first encapsulation layer 510 can be prepared through a chemical vapor deposition (CVD) process.

Optionally, the encapsulation layer 500 may further include a second encapsulation layer 520 disposed on a side of the first encapsulation layer 510 facing away from the baseplate 100. A material of the second encapsulation layer 520 may include an organic material so that the second encapsulation layer 520 can have relatively good flowability and a surface of a side of the second encapsulation layer 520 facing away from the baseplate 100 can be relatively flat. Optionally, the second encapsulation layer 520 can be prepared through inkjet printing (IJP) technology.

Optionally, the encapsulation layer 500 may further include a third encapsulation layer 530 disposed on the side of the second encapsulation layer 520 facing away from the baseplate 100, and a touch electrode 600 may be disposed on a side of the third encapsulation layer 530 facing away from the baseplate 100. A material of the third encapsulation layer 530 includes an inorganic material so that the third encapsulation layer 530 has a relatively good encapsulation ability to further reduce an effect of vapors on the sub-pixel 400. Optionally, the first encapsulation layer 530 can be prepared through the CVD process.

In some optional embodiments, the first encapsulation layer 510 includes a first encapsulation portion 511 corresponding to the light-emitting unit 420 and the second electrode 430, and the orthographic projection of the first defining opening 310 on the baseplate 100 is located within an orthographic projection of the first encapsulation portion 511 on the baseplate 100.

In these optional embodiments, the first encapsulation portion 511 completely covers the first defining opening 310 so that the first encapsulation portion 511 can provide more comprehensive protection to the sub-pixel 400.

Optionally, the first encapsulation portion 511 extends from the first defining opening 310 to the side of the isolation structure 300 facing away from the baseplate 100 to increase a distribution area of the first encapsulation portion 511 and improve a sealing effect of the first encapsulation portion 511.

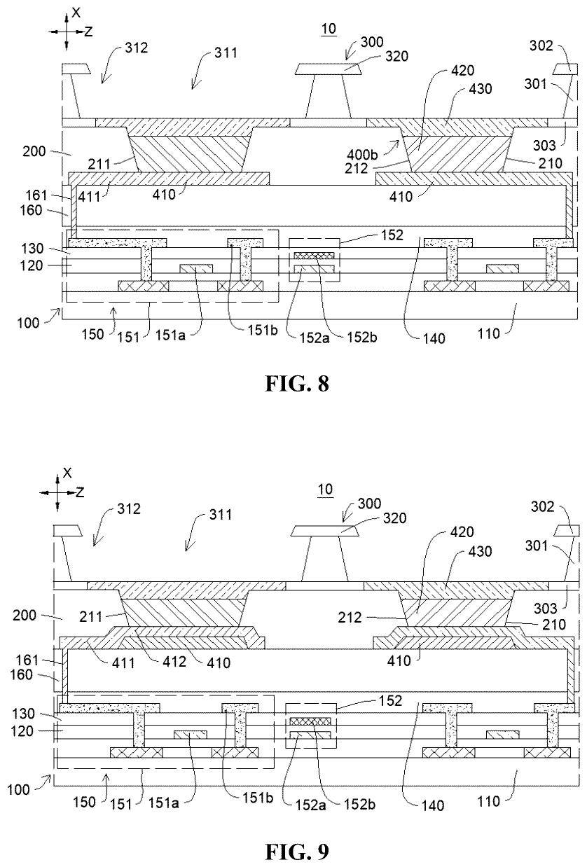

In some optional embodiments, as shown in FIGS. 1 to 3, the display panel 10 further includes one or more connection portions 411, and the connection portion 411 is connected to the first electrode 410, and the baseplate 100 includes one or more driver circuits 150 and a planarization layer 160 disposed on a side of the driver circuits 150 facing the sub-pixels 400. One or more connecting holes 161 are disposed on the planarization layer 160, and the connection portion 411 is connected to the driver circuit 150 via the connecting hole 161. As shown in FIG. 8, a material of the connection portion 411 includes a light-transmissive material, where an orthographic projection of the connection portion 411 on the baseplate 100 is at least partially located within the orthographic projection of the second opening region 312 on the baseplate 100; or, as shown in FIGS. 2 and 3, an orthographic projection of the connection portion 411 on the baseplate 100 is located outside the orthographic projection of the second opening region 312 on the baseplate 100.

In these optional embodiments, the first electrode 410 may be connected to the driver circuit 150 via the connection portion 411, and the material of the connection portion 411 may include the light-transmissive material to improve an effect of the connection portion 411 on the transmittance of the display panel 10. As shown in FIG. 8, when the material of the connection portion 411 includes the light-transmissive material, at least a portion of the connection portion 411 may be correspondingly located in the second opening region 312. As shown in FIGS. 2 and 3, when the material of the connection portion 411 includes no light-transmissive material, the connection portion 411 may be misaligned with the second opening region 312, that is, the orthographic projection of the connection portion 411 on the baseplate 100 is located outside the orthographic projection of the second opening region 312 on the baseplate 100 to improve an effect of the connection portion 411 on the transmittance of the second opening region 312.

When the material of the connection portion 411 includes the light-transmissive material, the material of the connection portion 411 may include at least one of indium tin oxide, indium zinc oxide or zinc oxide so that the connection portion 411 has a good transmittance and conductivity performance.

In some optional embodiments, as shown in FIG. 9, the light-emitting functional layer 40 further includes a second conductive layer 412, where the second conductive layer 412 is located on a side of the first electrode 410 facing the baseplate 100 or facing away from the baseplate 100 and is in contact with the first electrode 410, a transmittance of the second conductive layer 412 is greater than a transmittance of the first electrode 410, and the connection portion 411 and the second conductive layer 412 are disposed in the same layer and are made of the same material.

In these optional embodiments, the second conductive layer 412 is disposed on the side of the first electrode 410 facing or facing away from the baseplate 100. A distribution area of the second conductive layer 412 is relatively large, and the connection portion 411 and the second conductive layer 412 are disposed in the same layer and are made of the same material, that is, the connection portion 411 and the conductive layer are integrally disposed, thereby improving a connection yield between the connection portion 411 and the first electrode 410. A relatively high transmittance of the second conductive layer 412 can improve an effect of the second conductive layer 412 on the transmittance of the display panel 10.

Optionally, the orthographic projection of the second opening region 312 on the baseplate 100 at least partially overlaps an orthographic projection of the second conductive layer 412 on the baseplate 100. That is, at least a portion of the second conductive layer 412 is disposed in correspondence to the second opening region 312. A relatively high transmittance of the second conductive layer 412 has a relatively low effect on the transmittance of the second opening region 312 and can increase the distribution area of the second conductive layer 412, thereby improving the case where a light-emitting area is affected by the misalignment of the light-emitting unit 420 with the first electrode 410 due to a process error.

Preferably, a material of the second conductive layer 412 includes at least one of indium tin oxide, indium zinc oxide or zinc oxide so that the second conductive layer 412 has a transmittance and conductivity performance.

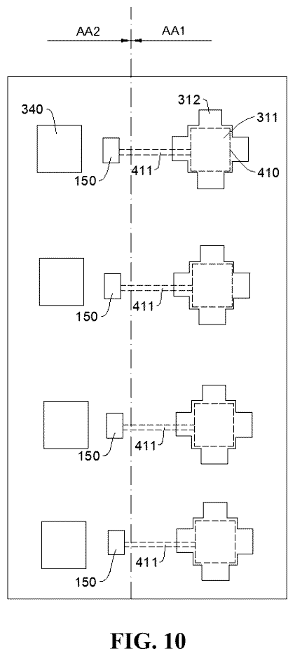

In some optional embodiments, as shown in FIG. 10, the display panel 10 includes a first display region AA1 and a second display region AA2, where a transmittance of the first display region AA1 is greater than a transmittance of the second display region AA2, the one or more driver circuits 150 are located in the second display region AA2, the first electrodes 410 connected to the connection portions 411 are located in the first display region AA1, the material of the connection portion 411 includes the light-transmissive material, and the connection portion 411 extends from the first display region AA1 to the second display region AA2.

In these optional embodiments, the transmittance of the first display region AA1 is greater than the transmittance of the second display region AA2, and the first display region AA1 can be used for achieving the under-screen integration of photosensitive modules. The connection portion 411 extends from the first display region AA1 to the second display region AA2, thereby facilitating disposing the driver circuit 150 for driving the first display region AA1 in the second display region AA2 to further improve the transmittance of the display panel 10.

Optionally, the isolation structure 300 encloses to form one or more third defining openings 340 located in the second display region AA2, and the third defining opening 340 may not include the second opening region 312.

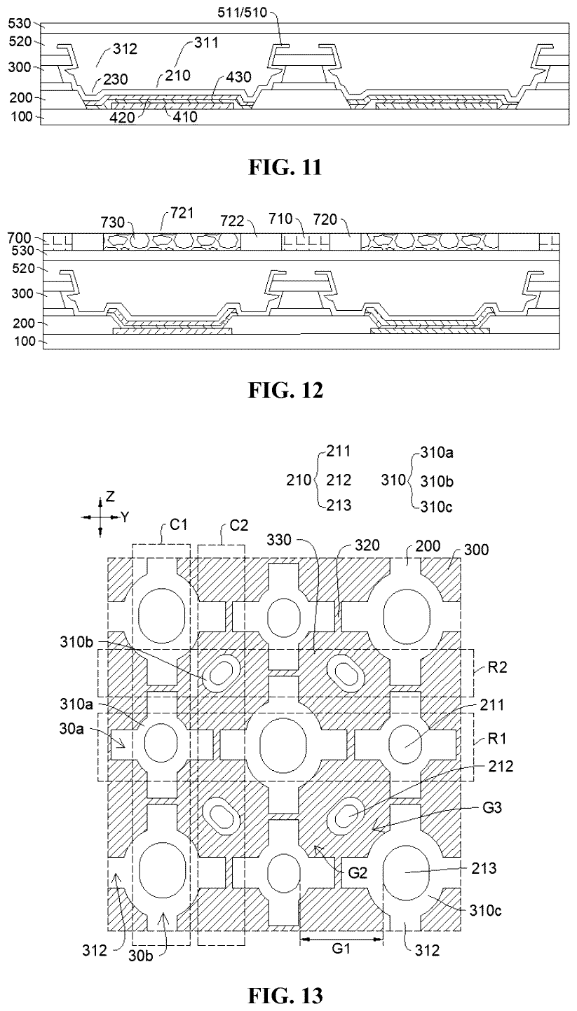

As mentioned above, the display panel 10 further includes a pixel defining layer, and the pixel defining layer includes a pixel defining portion 200 and one or more pixel openings 210 formed by enclosure of the pixel defining portion 200. The isolation structure 300 is disposed on a side of the pixel defining portion 200 facing away from the baseplate 100, a pixel opening 210 is communicated with a first defining opening 310, and the light-emitting unit 420 is at least partially located in the pixel opening 210. As shown in FIGS. 1 to 9, a material of the pixel defining portion 200 includes a light-transmissive material. Alternatively, as shown in FIG. 11, one or more defining layer openings 230 are disposed on the pixel defining portion 200, and an orthographic projection of the defining layer opening 230 on the baseplate 100 at least partially overlaps the orthographic projection of the second opening region 312 on the baseplate 100, that is, a defining layer opening 230 corresponding to the second opening region 312 is disposed on the pixel defining portion 200 to further improve a transmittance at a position where the second opening region 312 is located. As shown in FIG. 11, the defining layer opening 230 and the pixel opening 210 are communicated with each other. In other embodiments, the defining layer opening 230 and the pixel opening 210 may be spaced apart from each other, that is, a portion of the pixel defining portion 200 exists between the defining layer opening 230 and the pixel opening 210.

In these optional embodiments, the pixel opening 210 is communicated with the first defining opening 310 so that light emitted by the light-emitting unit 420 in the pixel opening 210 can be emitted via the first defining opening 310. The material of the pixel defining portion 200 may include the light-transmissive material to improve the transmittance of the display panel 10. When a material of the pixel defining layer is not a light-transmissive material, the defining layer opening 230 corresponding to the second opening region 312 is disposed on the pixel defining portion 200 to further improve the transmittance at the position where the second opening region 312 is located.

In some optional embodiments, as shown in FIG. 12, the display panel 10 may further include a light-filtering layer 700 located on a side of the light-emitting functional layer 40 facing away from the baseplate 100. When the display panel 10 includes the encapsulation layer 500, the light-filtering layer 700 may be located on a side of the encapsulation layer 500 facing away from the baseplate 100 to improve an effect of the light-filtering layer 700 on the light-emitting functional layer 40 and improve an encapsulation effect of the encapsulation layer 500.

Optionally, the light-filtering layer 700 includes a light-shielding defining portion 710, one or more second defining openings 720 formed by enclosure of the light-shielding defining portion 710, and one or more light-filtering units 730, and the light-filtering unit 730 is at least partially located at the second defining opening 720. The second defining openings 720 include one or more third opening regions 721 and one or more fourth opening regions 722, where an orthographic projection of the fourth opening region 722 on the baseplate 100 at least partially overlaps the orthographic projection of the second opening region 312 on the baseplate 100, and the light-filtering unit 730 is located in the third opening region 721.

In these optional embodiments, the light-shielding defining portion 710 encloses to form the second defining openings 720, the third opening region 721 and the fourth opening region 722 are disposed in the second defining opening 720, and the third opening region 721 disposed in correspondence to the first opening region 311 may be used to accommodate the light-filtering unit 730, thereby filtering the light emitted by the light-emitting unit. The fourth opening region 722 is disposed in correspondence to at least a portion of the second opening region 312, that is, no light-shielding defining portion 710 is correspondingly disposed in at least a portion of the second opening region 312, thereby further improving the transmittance of the second opening region 312.

Optionally, an orthographic projection of the light-filtering unit 730 on the baseplate 100 is at least partially located outside the orthographic projection of the fourth opening region 722 on the baseplate 100 to improve an effect of the light-filtering unit 730 on a transmittance of a position where the fourth opening region 722 is located.

Optionally, the light-filtering unit 730 covers at least a portion of the light-shielding defining portion 710. The light-filtering unit 730 covers a surface of the light-shielding defining portion 710 facing away from the baseplate 100 so that the light-filtering unit 730 can reduce a reflectance of the surface of the light-shielding defining portion 710 facing away from the baseplate 100, thereby improving a display effect of the display panel 10.

In some optional embodiments, as shown in FIGS. 2 and 3, a driver circuit layer is disposed on the baseplate 100 and includes at least one light-transmissive structure, where an orthographic projection of a light-transmissive structure on the baseplate 100 at least partially overlaps an orthographic projection of a second opening region 312 on the baseplate 100.

In these optional embodiments, the light-transmissive structure is disposed in the driver circuit layer and corresponds to the second opening region 312, thereby improving the transmittance of the second opening region 312.

Optionally, the driver circuit layer includes at least one conductive functional portion, where an orthographic projection of a conductive functional portion on the baseplate 100 is located outside an orthographic projection of a second opening region 312 on the baseplate 100. A material of the conductive functional portion generally includes a light-shielding metal material. The orthographic projection of the conductive functional portion on the baseplate 100 is located outside the orthographic projection of the second opening region 312 on the baseplate 100, thereby improving an effect of the conductive functional portion on the transmittance of the second opening region 312. Optionally, gaps are formed between multiple conductive functional portions, and light-transmissive structures are formed by the gaps. The conductive functional portion includes signal lines, for example, a data signal line, a scan signal line, a power signal line, and a light emission control signal line. The conductive functional portion may further include elements such as a semiconductor portion, a first capacitor plate and a second capacitor plate. A gap exists between signal lines, between a signal line and an element or between elements to form the light-transmissive structure, thereby improving the transmittance of the display panel.

The light-shielding portion 300b on the isolation portion 300a is disposed in multiple manners. For example, as shown in FIGS. 2 and 3, the isolation structure 300 includes a first isolation portion 301 and a second isolation portion 302 that are stacked in a direction facing away from the baseplate 100, where the second isolation portion 302 protrudes from the first isolation portion 301 toward the first defining opening 310, that is, an orthographic projection of the first isolation portion 301 on the baseplate 100 is located within an orthographic projection of the second isolation portion 302 on the baseplate 100.

In these optional embodiments, the second isolation portion 302 protrudes from the first isolation portion 301 toward the first defining opening 310 so that while evaporating the light-emitting unit 420 and the second electrode 430 of the display panel 10, the second isolation portion 302 located on a periphery of the first defining opening 310 can block at least some of the materials for preparing the light-emitting unit 420 and the second electrode 430 to better separate the light-emitting unit 420 and the second electrode 430 between adjacent sub-pixels 400, thereby facilitating the formation of multiple sub-pixels 400 disposed at intervals. Therefore, a fine mask plate does not need to be disposed while evaporating light-emitting unit 420 and the second electrode 430 of the display panel 10. For example, while evaporating the light-emitting unit 420 and the second electrode 430, a fine metal mask (FMM) does not need to be disposed, thereby better reducing a production and manufacturing cost of the display panel 10.

Optionally, the second isolation portion 302 located on the periphery of the first defining opening 310 can protrude from the first isolation portion 301 so that the materials for the light-emitting unit 420 and the second electrode 430 can be better separated at the isolation structure 300 on the periphery of the first defining opening 310 while evaporating the light-emitting unit 420 and the second electrode 430 of the display panel 10.

Optionally, the light-shielding portion 300b includes the first isolation portion 301 and/or the second isolation portion 302. The light-transmissive gap TG may be located between an orthographic projection of an edge of the first isolation portion 301 and/or the second isolation portion 302 on the baseplate 100 and the orthographic projection of the first electrode 410 on the baseplate 100.

Optionally, when a material of the second isolation portion 302 includes a light-transmissive material, the light-shielding portion 300b includes the first isolation portion 301, that is, the light-transmissive gap TG is located between the orthographic projection of the edge of the first isolation portion 301 on the baseplate 100 and the orthographic projection of the first electrode 410 on the baseplate 100.

In some other optional embodiments, the isolation structure 300 may further include a third isolation portion 303, where the third isolation portion 303 protrudes from the first isolation portion 301 toward the first defining opening 310, that is, the orthographic projection of the first isolation portion 301 on the baseplate 100 is located within an orthographic projection of the third isolation portion 303 on the baseplate 100. That is, sizes of the second isolation portion 302 and the third isolation portion 303 are both greater than a size of the first isolation portion 301.

The third isolation portion 303 protrudes from the first isolation portion 301 toward the first defining opening 310 so that the third isolation portion 303 may have a relatively large extension size and the third isolation portion 303 may have a relatively large area for being connected to the second electrode 430, thereby better improving the reliability of the connection between the isolation structure 300 and the second electrode 430. A material of the third isolation portion 303 may include a conductive material.

Optionally, the light-shielding portion 300b may include the second isolation portion 302 and/or the third isolation portion 303.

Optionally, when the material of the second isolation portion 302 is the light-transmissive material, the light-shielding portion 300b includes the third isolation portion 303, that is, the light-transmissive gap TG is located between an orthographic projection of an edge of the third isolation portion 303 on the baseplate 100 and the orthographic projection of the first electrode 410 on the baseplate 100.

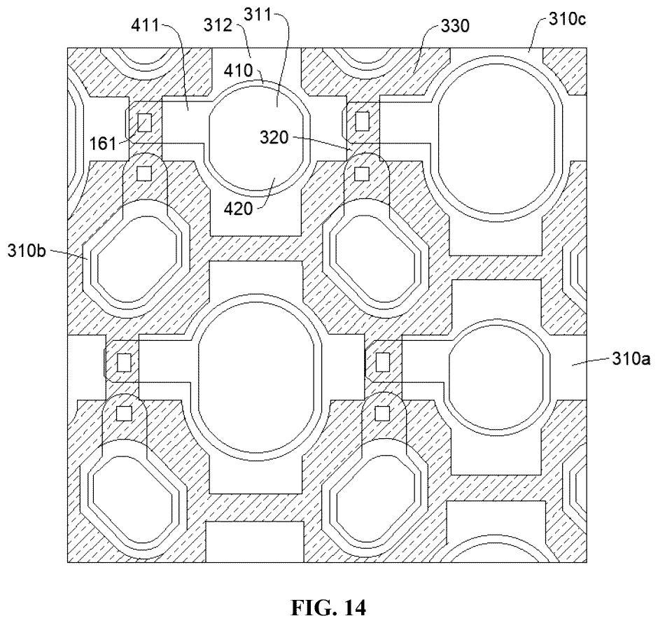

In some optional embodiments, as shown in FIGS. 13 to 16, the one or more first defining openings 310 include one or more first type of defining openings 310a, one or more second type of defining openings 310b and one or more third type of defining openings 310c, where the sub-pixels 400 include one or more first type of sub-pixels 400a corresponding to one or more first type of defining openings 310a, one or more second type of sub-pixels 400b corresponding to one or more second type of defining openings 310b and one or more third type of sub-pixels 400c corresponding to one or more third type of defining openings 310c. The first type of sub-pixel 400a, the second type of sub-pixel 400b and the third type of sub-pixel 400c can be used for emitting light of different colors. For example, the first type of sub-pixel 400a is a red sub-pixel, the second type of sub-pixel 400b is a green sub-pixel, and the third type of sub-pixel 400c is a blue sub-pixel. For example, the first type of sub-pixel 400a is used for emitting red light, the second type of sub-pixel 400b is used for emitting green light, and the third type of sub-pixel 400c is used for emitting blue light. A material of a light-emitting unit 420 of the first type of sub-pixel 400a, a material of a light-emitting unit 420 of the second type of sub-pixel 400b and a material of a light-emitting unit 420 of the third type of sub-pixel 400c may be at least partially different to facilitate the correspondence of the emitted colors of the first type of sub-pixel 400a, the second type of sub-pixel 400b and the third type of sub-pixel 400c.

When the first defining opening 310 includes the first type of defining opening 310a, the second type of defining opening 310b and the third type of defining opening 310c that are described above, at least one of the first type of defining opening 310a, the second type of defining opening 310b and the third type of defining opening 310c includes the first opening region 311 and the second opening region 312, where one second opening region 312 is disposed on a periphery of at least one first opening region 311, or more than two second opening regions 312 are distributed on a periphery of at least one first opening region 311 at intervals. That is, at least one of the first type of defining opening 310a, the second type of defining opening 310b and the third type of defining opening 310c can be expanded to form the second opening region 312 to improve the transmittance of the display panel 10.

The first type of sub-pixel 400a, the second type of sub-pixel 400b and the third type of sub-pixel 400c are arranged in multiple manners. For example, the first type of sub-pixels 400a and the third type of sub-pixels 400c are alternately arranged along a first direction Y to form a first pixel row R1, multiple second type of sub-pixels 400b are arranged along the first direction Y in sequence to form a second pixel row R2, the first pixel row R1 and the second pixel row R2 are alternately arranged along a second direction Z, the first type of sub-pixels 400a and the third type of sub-pixels 400c are alternately arranged along the second direction Z to form a first pixel column C1, and the multiple second type of sub-pixels 400b are arranged along the second direction Z in sequence to form a second pixel column C2.

Optionally, the first pixel column C1 and the second pixel column C2 are also alternately arranged along the first direction Y so that the distribution of multiple sub-pixels 400 of different colors is more uniform to improve a light emission effect of the display panel 10.

Optionally, the second opening region 312 may be correspondingly located between the first type of sub-pixel 400a and the third type of sub-pixel 400c that are adjacent along the first direction Y and/or the second direction Z.

In these optional embodiments, when multiple sub-pixels 400 are arranged to form the first pixel row R1, the second pixel row R2, the first pixel column C1 and the second pixel column C2, corresponding multiple first defining openings 310 are also arranged in the above manners. In the above arrangement manners, generally, the spacing between adjacent first type of sub-pixel 400a and third type of sub-pixel 400c is relatively large. The second opening region 312 is correspondingly disposed between a first type of sub-pixel 400a and a third type of sub-pixel 400c that are adjacent along the first direction Y and/or the second direction Z, thereby facilitating appropriately increasing a distribution area of the second opening region 312 and improving the transmittance of the display panel 10.

Optionally, an area of an orthographic projection of the second type of sub-pixel 400b on the baseplate 100 is less than an area of an orthographic projection of the first type of sub-pixel 400a on the baseplate 100. Optionally, the area of the orthographic projection of the second type of sub-pixel 400b on the baseplate 100 is less than an area of an orthographic projection of the third type of sub-pixel 400c on the baseplate 100.

In these optional embodiments, an area of the second type of sub-pixel 400b is relatively small, that is, a distribution area of the green sub-pixel 400 is relatively small, while distribution areas of the blue sub-pixel 400 and the red sub-pixel 400 are relatively large, thereby improving the light emission effect.

In addition, when the area of the second type of sub-pixel 400b is relatively small, a distance between the second type of sub-pixel 400b and the first type of sub-pixel 400a and a distance between the second type of sub-pixel 400b and the third type of sub-pixel 400c are relatively small, while a distance between the first type of sub-pixel 400a and the third type of sub-pixel 400c is relatively large, thereby facilitating disposing the second opening region 312 between the first type of sub-pixel 400a and the third type of sub-pixel 400c.

In some optional embodiments, as shown in FIGS. 13 and 14, each of the first type of defining opening 310a and the third type of defining opening 310c includes one or more first opening regions 311 and one or more second opening regions 312, a portion of second opening regions 312 in the display panel are disposed in the first type of defining openings 310a, and another portion of the second opening regions 312 in the display panel are disposed in the third type of defining openings 310c.

In these optional embodiments, the first opening region 311 and the second opening region 312 are disposed in the first type of defining opening 310a and the third type of defining opening 310c. The second opening region 312 is located between the first type of defining opening 310a and the third type of defining opening 310c. Some second opening regions 312 are disposed in the first type of defining openings 310a, and other second opening regions 312 are disposed in the third type of defining openings 310c, thereby simplifying a form of the isolation structure 300 on the basis of improving the transmittance of the display panel 10.

Optionally, multiple second opening regions 312 are disposed on a periphery of the first opening region 311 of the first type of defining opening 310a at intervals. For example, two second opening regions 312 are disposed on two sides of the first type of defining opening 310a, respectively, or four second opening regions 312 are disposed on two sides of the first type of defining opening 310a in the first direction Y and two sides of the first type of defining opening 310a in the second direction Z. That is, two second opening regions 312 are located on two sides of the first opening region 311 of the first type of defining opening 310a in the first direction Y, and/or two second opening regions 312 are located on two sides of the first opening region 311 of the first type of defining opening 310a in the second direction Z. Multiple second opening regions 312 are disposed in the same first type of defining opening 310a, thereby further improving the transmittance.

Optionally, one or more second opening regions 312 are disposed on each of a side of the first opening region 311 of the first type of defining opening 310a in the first direction Y and a side of the first opening region 311 of the first type of defining opening 310a in the second direction Z, thereby further increasing the distribution area of the second opening region 312.

Optionally, multiple second opening regions 312 are disposed on a periphery of the first opening region 311 of the third type of defining opening 310c at intervals. For example, two second opening regions 312 are disposed on two sides of the third type of defining opening 310c, respectively, or four second opening regions 312 are disposed on two sides of the third type of defining opening 310c in the first direction Y and two sides of the third type of defining opening 310c in the second direction Z. That is, two second opening regions 312 are located on two sides of the first opening region 311 of the third type of defining opening 310c in the first direction Y, and/or two second opening regions 312 are located on two sides of the first opening region 311 of the third type of defining opening 310c in the second direction Z. Multiple second opening regions 312 are disposed in the same third type of defining opening 310c, thereby further improving the transmittance.

Optionally, one or more second opening regions 312 are disposed on each of a side of the first opening region 311 of the third type of defining opening 310c in the first direction Y and a side of the first opening region 311 of the third type of defining opening 310c in the second direction Z, thereby further increasing the distribution area of the second opening region 312.

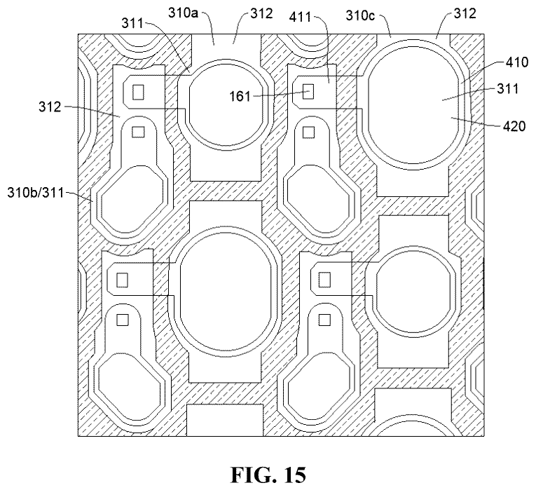

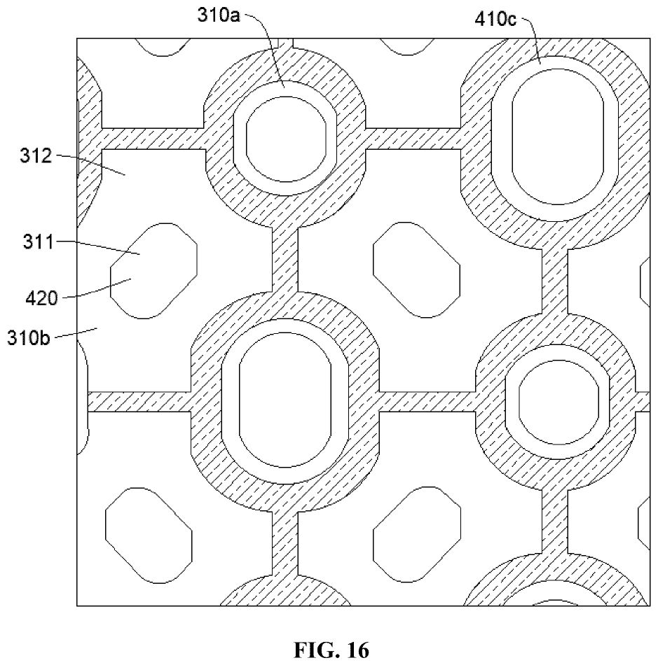

As shown in FIG. 15, in some other optional embodiments, the second type of defining opening 310b includes one or more first opening regions 311 and one or more second opening regions 312, and at least one second opening region 312 is disposed in the second type of defining opening 310b and is located on at least one side of the first opening region 311 of the second type of defining opening 310b in the first direction Y and/or the second direction Z.

In these optional embodiments, the second opening region 312 may also be disposed in the second type of defining opening 310b.

Optionally, the first pixel row R1 is misaligned with the second pixel row R2, and the first pixel column C1 is misaligned with the second pixel column C2 so that the second type of sub-pixel 400b may be correspondingly located between the first type of sub-pixel 400a and the third type of sub-pixel 400c that are adjacent along the first direction Y and/or the second direction Z. That is, the second type of defining opening 310b is correspondingly located between the first type of defining opening 310a and the third type of defining opening 310c that are adjacent along the first direction Y and/or the second direction Z.

When the second opening region 312 is located between the first type of defining opening 310a and the third type of defining opening 310c that are adjacent along the first direction Y and/or the second direction Z, the second opening region 312 is located on a side of the second type of defining opening 310b in the first direction Y and/or the second direction Z. In the embodiment of the present application, the second opening region 312 is disposed in the second type of defining opening 310b, the distribution form of the isolation structure 300 can also be simplified.

Optionally, when the second type of defining opening 310b includes the second opening region 312, the first type of defining opening 310a or the third type of defining opening 310c may also include the second opening region 312.

For example, the first type of defining opening 310a and the second type of defining opening 310b include the first opening region 311 and the second opening region 312, at least one second opening region 312 is disposed in the second type of defining opening 310b and is located on at least one side of the first opening region 311 of the second type of defining opening 310b in the second direction Z, and at least one second opening region 312 is disposed in the first type of defining opening 310a and is located on at least one side of the first opening region 311 of the first type of defining opening 310a in the second direction Z.

In these optional embodiments, both the first type of defining opening 310a and the second type of defining opening 310b include the second opening region 312 to further increase the distribution area of the second opening region 312 and improve the transmittance of the display panel 10.

Optionally, the third type of defining opening 310c includes the first opening region 311 and the second opening region 312, where at least one second opening region 312 is disposed in the third type of defining opening 310c and is located on at least one side of the first opening region 311 of the third type of defining opening 310c in the second direction Z.

In these optional embodiments, all of the first type of defining opening 310a, the second type of defining opening 310b and the third type of defining opening 310c include the second opening region 312 to further increase the distribution area of the second opening region 312 and improve the transmittance of the display panel 10.

Optionally, two second opening regions 312 are located on two sides of the first opening region 311 of the first type of defining opening 310a in the second direction Z. The first type of defining opening 310a includes two second opening regions 312. The two second opening regions facilitate symmetrical distribution about the first opening region 311 of the first type of defining opening 310a, thereby simplifying the distribution shape of the isolation structure 300.

Optionally, the second opening region 312 includes a first type of light-transmissive region 312a located between the first type of sub-pixel 400a and the third type of sub-pixel 400c that are adjacent along the first direction Y, where the first type of light-transmissive region 312a is disposed in the third type of defining opening 310c. The second opening region 312 between the first type of sub-pixel 400a and the third type of sub-pixel 400c that are adjacent along the first direction Y is disposed on a side of the third type of sub-pixel 400c in the second direction Z. The first type of light-transmissive region 312a is disposed on the second type of defining opening 310b, thereby simplifying the distribution shape of the isolation structure 300.

Optionally, the second opening region 312 includes a second type of light-transmissive region 312b located between the first type of sub-pixel 400a and the second type of sub-pixel 400b that are adjacent along the second direction Z, where the second type of light-transmissive region 312b is disposed in the first type of defining opening 310a and/or the third type of defining opening 310c. The second type of light-transmissive region 312b is located on a side of the first type of defining opening 310a and/or the second type of defining opening 310b in the first direction Y. The second type of light-transmissive region 312b is disposed in the first type of defining opening 310a and/or the second type of defining opening 310b, thereby simplifying the distribution shape of the isolation structure 300.

In some other optional embodiments, as shown in FIG. 16, the second opening regions 312 are disposed on two sides of the first opening region 311 of the second type of defining opening 310b in the first direction Y and two sides of the first opening region 311 of the second type of defining opening 310b in the second direction Z.

In these optional embodiments, multiple second opening regions 312 are all disposed in the second type of defining opening 310b, and no second opening region 312 may be disposed in the first type of defining opening 310a and the third type of defining opening 310c, thereby evolving shapes of the first type of defining opening 310a and the third type of defining opening 310c.

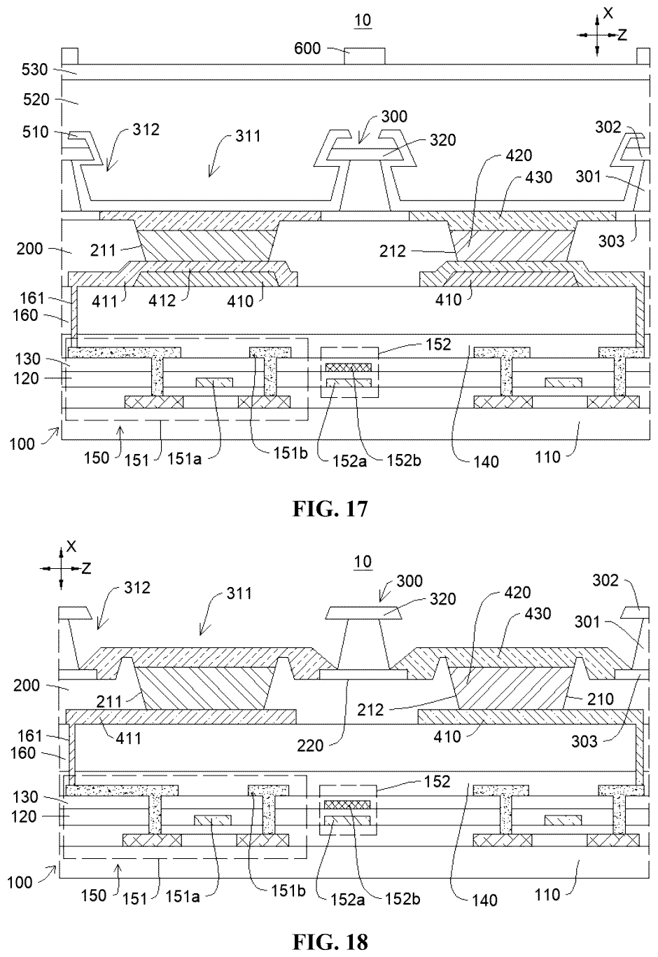

In some other optional embodiments, as shown in FIG. 17, the display panel 10 may further include a touch electrode 600. The touch electrode 600 may be disposed on the side of the encapsulation layer 500 facing away from the baseplate 100. An orthographic projection of the touch electrode 600 on the baseplate 100 is located within an orthographic projection of the isolation structure 300 on the baseplate 100.

In the optional embodiment, the touch electrode 600 may be connected to a touch signal line of the display panel 10 to receive a touch signal so that the touch electrode 600 can be used for participating in the touch sensing work of the display panel 10. The orthographic projection of the touch electrode 600 on the baseplate 100 is located within the orthographic projection of the isolation structure 300 on the baseplate 100 so that the touch electrode 600 is not easy to block the first opening region 311 and the second opening region 312 in the thickness direction X of the display panel 10 and the touch electrode 600 is not easy to block light in the display panel 10 that passes through the first opening region 311 and the second opening region 312, thereby better improving the light transmission of the display panel 10.

Optionally, a minimum spacing between the touch electrode 600 and a first opening region 311 on one side of the touch electrode 600 may be equal to a minimum spacing between the touch electrode 600 and a first opening region 311 on the other side of the touch electrode 600, and/or a minimum spacing between the touch electrode 600 and a second opening region 312 on one side of the touch electrode 600 may be equal to a minimum spacing between the touch electrode 600 and a second opening region 312 on the other side of the touch electrode 600 so that the touch electrode 600 may be centrally arranged above the isolation structure 300 and blocking effects of the touch electrode 600 on light emitted by sub-pixels 400 in pixel openings 210 on two sides of the touch electrode 600 may be relatively similar, thereby better improving a color cast difference of the display panel 10.

Optionally, a material of the isolation structure 300 includes a conductive material, and the second electrode 430 may be at least partially located within the first defining opening 310 and may be connected to the isolation structure 300 so that second electrodes 430 between adjacent sub-pixels 400 can be electrically connected via the isolation structure 300, that is, second electrodes 430 in adjacent first defining openings 310 can be electrically connected to each other via the isolation structure 300 to form a surface electrode, thereby facilitating the control of the second electrode 430 in the display panel 10.

In some embodiments of the present application, the second opening region 312 may be a light-transmissive opening formed through the sinking of the surface on the side of the isolation structure 300 facing the first opening region 311 so that the light-transmissive structure (the second opening region 312) for light transmission provided in the embodiment of the present application can be moved to the periphery of the first opening region 311. Compared with the related art that a light-transmissive structure (for example, a light-transmissive opening) that is not connected to a first opening region 311 is disposed in an isolation structure 300, the isolation structure 300 of the display panel 10 provided in the embodiment of the present application is not easily divided into multiple mutually spaced portions by the light-transmissive structure for light transmission, thereby improving the convenience of arranging the isolation structure 300 and facilitating that the second electrodes 430 between adjacent sub-pixels 400 are electrically connected via the isolation structure 300.

As shown in FIGS. 1 to 13, in some optional embodiments, the isolation structure 300 includes a first isolation segment 320 and a second isolation segment 330 that are connected to each other, where a width of the first isolation segment 320 is less than a width of the second isolation segment 330, and the first isolation segment 320 is located on a side of the second opening region 312. The first isolation segment 320 has a relatively small width, thereby increasing the distribution area of the second opening region 312.

Optionally, the first isolation segment 320 and a portion of the second isolation segment 330 enclose to form the second opening region 312.

Optionally, the second electrode 430 can be lapped with both the first isolation segment 320 and a portion of the second isolation segment 330 to increase a lapping area between the second electrode 430 and the isolation structure 300 and reduce a contact resistance between the second electrode 430 and the isolation structure 300.

Alternatively, as described above, a third hollowed-out opening 431 is disposed on the second electrode 430, the second electrode 430 and the first isolation segment 320 are spaced apart at a position where the third hollowed-out opening 431 is located, and the second electrode 430 is lapped with the second isolation segment 330 to further improve the transmittance of the display panel.

Optionally, the width of the first isolation segment 320 may refer to a spacing between surfaces of the first isolation segment 320 facing first opening regions 311 on two sides of the first isolation segment 320, for example, the width of the first isolation segment 320 may refer to a maximum spacing between the surfaces of the first isolation segment 320 facing the first opening regions 311 on the two sides of the first isolation segment 320. Optionally, the width of the second isolation segment 330 may refer to a spacing between surfaces of the second isolation segment 330 facing first opening regions 311 on two sides of the second isolation segment 330, for example, the width of the second isolation segment 330 may refer to a maximum spacing between the surfaces of the second isolation segment 330 facing the first opening regions 311 on the two sides of the second isolation segment 330.

Optionally, a width of a first isolation portion 301 of the first isolation segment 320 may be less than a width of a first isolation portion 301 of the second isolation segment 330. Optionally, a width of a second isolation portion 302 of the first isolation segment 320 may be less than a width of a second isolation portion 302 of the second isolation segment 330. Optionally, a width of a third isolation portion 303 of the first isolation segment 320 may be less than a width of a third isolation portion 303 of the second isolation segment 330.

The width of the first isolation portion 301 may refer to a spacing between surfaces of the first isolation portion 301 facing first opening regions 311 on two sides of the first isolation portion 301, for example, the width of the first isolation portion 301 may refer to a maximum spacing between the surfaces of the first opening regions 311 facing the first defining openings 310 on the two sides of the first isolation portion 301. The width of the second isolation portion 302 may refer to a spacing between surfaces of the second isolation portion 302 facing first opening regions 311 on two sides of the second isolation portion 302, for example, the width of the second isolation portion 302 may refer to a maximum spacing between the surfaces of the second isolation portion 302 facing the first opening regions 311 on the two sides of the second isolation portion 302. The width of the third isolation portion 303 may refer to a spacing between surfaces of the third isolation portion 303 facing first opening regions 311 on two sides of the third isolation portion 303, for example, the width of the third isolation portion 303 may refer to a maximum spacing between the surfaces of the third isolation portion 303 facing the first opening regions 311 on the two sides of the third isolation portion 303.

Optionally, the first isolation segment 320 is connected between two adjacent second isolation segments 330, and the second opening region 312 is formed between the adjacent second isolation segments 330.

In these optional embodiments, the width of the first isolation segment 320 is set to be less than the width of the second isolation segment 330 so that the isolation structure 300 can be sunk at a first isolation segment 320 with a relatively narrow width between two adjacent second isolation segments 330 to form the second opening region 312 and light can better pass through the second opening region 312 to penetrate the display panel 10, thereby improving the light transmission of the display panel 10.

As shown in FIG. 13, in some optional embodiments, a first spacing G1 is set between at least two adjacent pixel openings 210, a second spacing G2 is set between at least two adjacent pixel openings 210, and the first spacing G1 is greater than the second spacing G2. That is, the first spacing G1 and the second spacing G2 are formed between two different adjacent pixel openings 210, and the first spacing G1 is greater than the second spacing G2. Herein, the first spacing G1 is a first interval in a priority application (Application No. CN202410545864.5), and the second spacing G2 is a second interval in the priority application.

Optionally, the expression that the first spacing G1 is greater than the second spacing G2 may mean that a minimum spacing between two adjacent pixel openings 210 corresponding to the first spacing G1 is greater than a minimum spacing between two adjacent pixel openings 210 corresponding to the second spacing G2.

Optionally, the second opening region 312 may be located within the first spacing G1.

Optionally, the first isolation segment 320 may be located within the first spacing G1.

In these optional embodiments, the second opening region 312 and the first isolation segment 320 are disposed within the first spacing G1 with a relatively large size, that is, the second opening region 312 and the first isolation segment 320 are disposed between adjacent pixel openings 210 with a relatively large spacing, so that the second opening region 312 with a relatively large size may be arranged between adjacent pixel openings 210 with a relatively large spacing, thereby better improving the light transmission of the display panel 10. Moreover, the arrangement of the second opening region 312 is not easy to affect a size of the distance structure between pixel openings 210 with a relatively small spacing. For example, the second isolation segment 330 may be disposed within the second spacing G2 so that a relatively wide isolation structure 300 may be disposed between the pixel openings 210 with a relatively small spacing to reduce resistance.

In some optional embodiments, a third spacing G3 is set between at least two adjacent pixel openings 210, the first spacing G1 is greater than the third spacing G3, and the third spacing G3 is not equal to the second spacing G2. The expression that the first spacing G1 is greater than the third spacing G3 and the third spacing G3 is not equal to the second spacing G2 may mean that the minimum spacing between two adjacent pixel openings 210 corresponding to the first spacing G1 is greater than a minimum spacing between two adjacent pixel openings 210 corresponding to the third spacing G3 and the minimum spacing between two adjacent pixel openings 210 corresponding to the third spacing G3 is not equal to the minimum spacing between two adjacent pixel openings 210 corresponding to the second spacing G2.

Optionally, the second isolation segment 330 may be disposed within the third spacing G3 so that a relatively wide isolation structure 300 may be disposed between the pixel openings 210 with a relatively small spacing to reduce resistance.

Optionally, the pixel openings 210 include one or more first openings 211, one or more second openings 212 and one or more third openings 213. As an example, the first type of sub-pixel 400a may be at least partially located in the first opening 211, the second type of sub-pixel 400b may be at least partially located in the second opening 212, and the third type of sub-pixel 400c may be at least partially located in the third opening 213.

Optionally, a first spacing G1 is set between adjacent first opening 211 and third opening 213, a second spacing G2 is set between adjacent first opening 211 and second opening 212, and a third spacing G3 is set between adjacent second opening 212 and third opening 213. That is, the spacing between adjacent first opening 211 and third opening 213 may be greater than the spacing between adjacent first opening 211 and second opening 212, and the spacing between adjacent first opening 211 and third opening 213 may be greater than the spacing between adjacent second opening 212 and third opening 213.

Optionally, the second opening region 312 may be located between the first opening 211 and the third opening 213.

Optionally, the first isolation segment 320 may be located between the first opening 211 and the third opening 213.

In these optional embodiments, the second opening region 312 and the first isolation segment 320 are disposed between the first opening 211 and the third opening 213 with a relatively large spacing so that the second opening region 312 with a relatively large size may be arranged between adjacent pixel openings 210 with a relatively large spacing, thereby better improving the light transmission of the display panel 10.

In some embodiments of the present application, the pixel openings 210 are arranged in multiple manners.

In some optional embodiments, one or more first openings 211 and one or more third openings 213 may be alternately arranged along the first direction Y to form the first pixel column C1, and multiple second openings 212 may be arranged along the first direction Y at intervals to form the second pixel column C2.

Optionally, the first pixel column C1 and the second pixel column C2 are alternately arranged in the second direction Z.

Optionally, the second opening region 312 may be located within in the first pixel column C1.

Optionally, the first isolation segment 320 may be located in the first pixel column C1.

In these optional embodiments, the second opening region 312 and the first isolation segment 320 are disposed in the first pixel column C1 so that the second opening region 312 with a relatively large size may be arranged in the first pixel column C1 where a relatively large spacing exists between adjacent pixel openings 210, thereby better improving the light transmission of the display panel 10.

In some optional embodiments, one or more first openings 211 and one or more third openings 213 are alternately arranged along the second direction Z to form the first pixel row R1, and multiple second openings 212 are arranged along the second direction Z at intervals to form the second pixel row R2.

Optionally, the first pixel row R1 and the second pixel row R2 are alternately arranged in the first direction Y.

Optionally, the second opening region 312 is located in the first pixel row R1.

Optionally, the first isolation segment 320 is located in the first pixel low R1.

In these optional embodiments, the second opening region 312 and the first isolation segment 320 are disposed in the first pixel low R1 so that the second opening region 312 with a relatively large size may be arranged in the first pixel row R1 where a relatively large spacing exists between adjacent pixel openings 210, thereby better improving the light transmission of the display panel 10.

Optionally, as mentioned above, the isolation structure 300 includes a first isolation segment 320 and a second isolation segment 330.

Optionally, as mentioned above, the connecting hole 161 is disposed on the planarization layer 160, and at least some of the connecting holes 161 may be disposed at intervals along a straight line in an arrangement direction of the sub-pixel 400. For example, the connecting holes 161 may be disposed at intervals along the straight line in the first direction Y and/or the second direction Z to facilitate the arrangement of the connecting holes 161 below the isolation structure 300 so that an edge of the isolation structure 300 facing the first defining opening 310 is not easily affected by the arrangement of the connecting holes 161 to become concave.

As shown in FIG. 18, optionally, an accommodation recess 220 is disposed on the pixel defining portion 200, and the isolation structure 300 may be at least partially located in the accommodation recess 220 so that a height of the isolation structure 300 is not easy to be excessively large compared with that of the baseplate 100, thereby better reducing a thickness of the display panel 10.

As shown in FIGS. 1 to 18, embodiments in the first aspect of the present application provide a display panel 10. The display panel 10 includes a baseplate 100, an isolation structure 300 disposed on a side of the baseplate 100 and enclosing to form one or more first opening regions 311 and one or more sub-pixels 400, and a sub-pixel 400 is at least partially located in a first opening region 311, where one or more second opening regions 312 communicating with the first opening region 311 are disposed on a side of at least a portion of the isolation structure 300 facing the first opening region 311, and the second opening region 312 passes through the isolation structure 300 along a thickness direction X of the display panel 10.

The display panel 10 provided in the embodiments of the present application includes the baseplate 100, the isolation structure 300 and the sub-pixel 400. The isolation structure 300 is disposed on the side of the baseplate 100 and enclosed to form the first opening region 311, the sub-pixel 400 is at least partially located in the first opening region 311, and the isolation structure 300 can be used for dividing the sub-pixels 400 of the display panel 10. The second opening region 312 communicating with the first opening region 311 is disposed on the side of at least a portion of the isolation structure 300 facing the first opening region 311, and the second opening region 312 passes through the isolation structure 300 along the thickness direction X of the display panel 10 so that in the thickness direction X of the display panel 10, light can better penetrate the display panel 10 in the second opening region 312, thereby better improving the light transmission of the display panel 10.

Optionally, the second opening regions 312 are located on two sides of the first isolation segment 320 facing the first opening region 311, thereby better improving the arrangement density of the second opening region 312 and further improving the light transmission performance of the display panel 10.

As shown in FIGS. 2 and 3, in some optional embodiments, the display panel 10 further includes a pixel defining portion 200, where the pixel defining portion 200 encloses to form one or more pixel openings 210, and the sub-pixel 400 may be partially located in a pixel opening 210.

Optionally, a bonding surface between the first electrode 410 and the light-emitting unit 420 of the sub-pixel 400 may be located in the pixel opening 210 so that the light-emitting unit 420 in the pixel opening 210 can perform a better light-emitting display.

Optionally, the pixel opening 210 may be communicated with the first opening region 311. For example, the orthographic projection of the pixel opening 210 on the baseplate 100 is located within the orthographic projection of the first opening region 311 on the baseplate 100 so that the materials of the light-emitting unit 420 and the second electrode 430 can better enter the pixel opening 210 via the first opening region 311, thereby better increasing an amount of materials of the light-emitting unit 420 and the second electrode 430 that enters the pixel opening 210. The orthographic projection of the first opening region 311 on the baseplate 100 may refer to a projection region formed by the enclosure of an orthographic projection of an inner wall of the first opening region 311 on the baseplate 100. The orthographic projection of the pixel opening 210 on the baseplate 100 may refer to a projection region formed by the enclosure of an orthographic projection of an inner wall of the pixel opening 210 on the baseplate 100.

Optionally, the second opening region 312 is located on the side of the pixel defining portion 200 facing away from the baseplate 100. Optionally, the orthographic projection of the pixel opening 210 on the baseplate 100 does not overlap the orthographic projection of the second opening region 312 on the baseplate 100 so that the second isolation segment 330 enclosing to form the second opening region 312 is not easy to block the light-emitting display of the sub-pixel 400 in the pixel opening 210.

Optionally, the material of the pixel defining portion 200 may include an insulating material.

In these optional embodiments, the pixel defining portion 200 can also be used for participating in the division of the sub-pixels 400 of the display panel 10. The pixel defining portion 200 may be located between first electrodes 410 of adjacent sub-pixels 400 so that the first electrodes 410 between adjacent sub-pixels 400 can be insulated by the pixel defining portion 200. Moreover, the pixel defining portion 200 may also be located between the isolation structure 300 and the first electrode 410 so that the isolation structure 300 and the first electrode 410 can be insulated by the pixel defining portion 200 and the second electrode 430 and the first electrode 410 are not easily short-circuited by the isolation structure 300.

Optionally, a minimum spacing between an orthographic projection of the first isolation segment 320 on the baseplate 100 and the orthographic projection of the pixel opening 210 on the baseplate 100 is greater than a minimum spacing between an orthographic projection of the second isolation segment 330 on the baseplate 100 and the orthographic projection of the pixel opening 210 on the baseplate 100 so that the first isolation segment 320 can be better sunk along a direction facing away from the pixel opening 210 to form the second opening region 312 with a relatively large size compared with the second isolation segment 330, thereby further improving the light transmission of the display panel 10.

In some embodiments of the present application, relative positions between the isolation structure 300 and the pixel defining portion 200 are disposed in multiple manners.

In some optional embodiments, as shown in FIGS. 2 and 3, the isolation structure 300 is disposed on the side of the pixel defining portion 200 facing away from the baseplate 100, that is, the isolation structure 300 may be directly disposed on the pixel defining portion 200.

As shown in FIGS. 1 to 5, in some optional embodiments, the orthographic projection of the first electrode 410 on the baseplate 100 can at least partially overlap the orthographic projection of the isolation structure 300 on the baseplate 100. In this manner, the first electrode 410 may be partially located below the isolation structure 300, the first electrode 410 can better extend to a position below the isolation structure 300 via the edge of the isolation structure 300 facing the first defining opening 310, a film structure below the edge of the isolation structure 300 facing the first defining opening 310 may be relatively flat and when the isolation structure 300 is prepared through etching, an etching material is not easy to cause abnormal etching on the edge of the isolation structure 300, thereby better improving a preparation yield of the isolation structure 300. Moreover, the second electrode 430 above the first electrode 410 is not easily affected by the arrangement of the first electrode 410. The second electrode 430 can be smoothly connected to the edge of the isolation structure 300 facing the first defining opening 310, thereby better improving the reliability of the connection between the second electrode 430 and the isolation structure 300.

In some embodiments of the present application, the baseplate 100 is disposed in multiple manners. The baseplate 100 may include, for example, a substrate 110 and a driver circuit 150 disposed on the substrate 110. For example, the driver circuit 150 may include a transistor 151, a storage capacitor 152 and drive signal lines for connecting the devices. The transistor 151 includes a semiconductor, a gate 151a and a source and drain 151b. The storage capacitor 152 includes a first plate 152a and a second plate 152b.

Optionally, the baseplate 100 includes a first insulating layer 120, a second insulating layer 130 and a third insulating layer 140 that are stacked. As an example, the gate 151a and the first plate 152a may be located on a side of the first insulating layer 120 facing the substrate 110, the second plate 152b may be located between the first insulating layer 120 and the second insulating layer 130, and the source and drain 151b may be located between the second insulating layer 130 and the third insulating layer 140.

Optionally, the baseplate 100 further includes a planarization layer 160 disposed on a side of the transistor 151 facing the sub-pixel 400. For example, the planarization layer 160 may be disposed on a side of the third insulating layer 140 facing away from the baseplate 100.

Optionally, one or more connecting holes 161 may be disposed on the planarization layer 160, and the first electrode 410 can be connected to the transistor 151 via the connecting hole 161. For example, the first electrode 410 can be connected to the source and drain 151b of the transistor 151 via the connecting hole 161.

Optionally, an orthographic projection of the connecting hole 161 on the baseplate 100 may be located within the orthographic projection of the isolation structure 300 on the baseplate 100, that is, the connecting hole 161 may be located below the isolation structure 300 and may not be disposed on a side of the isolation structure 300 facing the first defining opening 310. In this manner, an edge of the isolation structure 300 facing the first opening region 311 and the second opening region 312 is not easily affected by the arrangement of the connecting hole 161 to become concave and when the isolation structure 300 is prepared through etching, the etching material is not easy to cause abnormal etching on the edge of the isolation structure 300, thereby better improving the preparation yield of the isolation structure 300. Moreover, the second electrode 430 above the first electrode 410 is not easily affected by the arrangement of the connecting hole 161. The second electrode 430 can be smoothly connected to the edge of the isolation structure 300 facing the first defining opening 310, thereby better improving the reliability of the connection between the second electrode 430 and the isolation structure 300.

The orthographic projection of the connecting hole 161 on the baseplate 100 may refer to a projection region formed by the enclosure of an orthographic projection of an inner wall of the connecting hole 161 on the baseplate 100.

As shown in FIG. 5, in some optional embodiments, the second conductive layer 412 is disposed on the side of the first electrode 410 facing away from the baseplate 100 in the direction facing away from the baseplate 100.

Optionally, the orthographic projection of the first electrode 410 on the baseplate 100 is located within the orthographic projection of the second conductive layer 412 on the baseplate 100.

Optionally, the orthographic projection of the first electrode 410 on the baseplate 100 may be located within the orthographic projection of the pixel opening 210 on the baseplate 100.

In these optional embodiments, the first electrode 410 may be mainly used as an anode of the display panel 10, and the second conductive layer 412 located above the first electrode 410 can be used for protecting the first electrode 410 so that when other films are patterned in the process steps of preparing the display panel 10, the first electrode 410 is not easily damaged. For example, when other films are etched, the second conductive layer can be used for blocking the etching material from etching the first electrode 410 so that the first electrode 410 can have relatively good structural stability.

In some optional embodiments, the transmittance of the second conductive layer 412 is greater than the transmittance of the first electrode 410.

Optionally, the material of the second conductive layer 412 includes at least one of indium tin oxide, indium zinc oxide or zinc oxide.

Optionally, a material of the first electrode 410 may include a metal material. For example, the material of the first electrode 410 may include silver so that the first electrode 410 can have a certain reflective ability to reflect light emitted by the light-emitting unit 420 above the first electrode 410, thereby better improving the display brightness of the display panel 10.

In these optional embodiments, the transmittance of the second conductive layer 412 is greater than the transmittance of the first electrode 410 so that the second conductive layer 41 may not cause an excessively large effect on the propagation of light and the light can better pass through the second conductive layer 412, thereby better improving the light transmission performance of the display panel 10.

Optionally, the baseplate 100 includes a transistor 151, and the connection portion 411 and the second conductive layer 412 are disposed in the same layer and can be connected to the transistor 151 so that the first electrode 410 can be electrically connected to the transistor 151 in the baseplate 100 via the second conductive layer 412 and the connection portion 411 and a size of the first electrode 410 may be relatively small to reduce a blocking effect of the first electrode 410 on light, thereby better improving the light transmission performance of the display panel 10. Moreover, since the transmittance of the second conductive layer 412 is greater than the transmittance of the first electrode 410, that is, the second conductive layer 412 is not easy to cause an excessively large blocking effect on the propagation of light, so that a size of the second conductive layer 412 may be relatively large, thereby facilitating the connection between the second conductive layer 412 and the transistor 151 via the connection portion 411.

In some embodiments of the present application, positions of the second opening region 312 and the first isolation segment 320 are arranged in multiple manners. The positions of the second opening region 312 and the first isolation segment 320 may be arranged according to spacings between adjacent pixel openings 210.

As shown in FIG. 13, optionally, the first opening region 311 includes a first type of first opening region 311 and a second type of first opening region 311. The first type of sub-pixel 400a may be at least partially located in the first type of first opening region 311, and the second type of sub-pixel 400b may be at least partially located in the second type of first opening region 311. That is, the first defining opening 310 includes a first type of defining opening 310a and a second type of defining opening 310b. The first type of sub-pixel 400a may be at least partially located in the first type of defining opening 310a, and the second type of sub-pixel 400b may be at least partially located in the second type of defining opening 310b.

Optionally, the first opening region 311 may further include a third type of first opening region 311. The third type of sub-pixel 400c may be at least partially located in the third type of first opening region 311. The first defining opening 310 may further include a third type of defining opening 310c. The third type of sub-pixel 400c may be at least partially located in the third type of defining opening 310c.

In some embodiments of the present application, the second opening region 312 may be disposed on a periphery of some particular first opening regions 311. Optionally, multiple second opening regions 312 may be provided, and the multiple second opening regions 312 may be disposed on a periphery of at least some of the first opening regions 311 at intervals to uniformly improve the light transmission of the periphery of the first opening regions 311.

In some optional embodiments, at least some of the second opening regions 312 may be disposed in the first type of defining opening 310a, and the first type of defining opening 310a having the second opening regions 312 constitutes a first light-transmissive region 30a of the isolation structure 300 so that the display panel 10 at the first light-transmissive region 30a can have relatively good light transmission. The first type of sub-pixel 400a may be at least partially located in the first light-transmissive region 30a.

Optionally, an area of an orthographic projection of the second type of defining opening 310b on the baseplate 100 may be less than an area of an orthographic projection of the first light-transmissive region 30a on the baseplate 100 so that the first light-transmissive region 30a can have a relatively large arrangement area and relatively good light transmission.

Optionally, multiple second opening regions 312 may be disposed on the periphery of the first opening region 311 of the first type of defining opening 310a at intervals to uniformly improve the light transmission of a periphery of the first type of defining opening 310a.

In some optional embodiments, at least some of the second opening regions 312 may be disposed in the third type of defining opening 310c, and the third type of defining opening 310c forms a second light-transmissive region 30b of the isolation structure 300 so that the display panel 10 at the second light-transmissive region 30b can have relatively good light transmission. The third type of sub-pixel 400c may be at least partially located in the second light-transmissive region 30b.

Optionally, an area of an orthographic projection of the second type of defining opening 310b on the baseplate 100 may be less than an area of an orthographic projection of the second light-transmissive region 30b on the baseplate 100 so that the second light-transmissive region 30b can have a relatively large arrangement area and relatively good light transmission.

Optionally, multiple second opening regions 312 may be disposed on the periphery of the first opening region 311 of the third type of defining opening 310c at intervals to uniformly improve the light transmission of a periphery of the third type of defining opening 310c.

Referring to FIGS. 1 to 18, embodiments in the first aspect of the present application further provide a display panel 10. The display panel 10 includes a baseplate 100, an isolation structure 300 disposed on a side of the baseplate 100 and enclosing to form one or more first opening regions 311 and a sub-pixel 400 at least partially located in a first opening region 311, where the isolation structure 300 includes a first isolation segment 320 and a second isolation segment 330 that are connected to each other, and a width of the first isolation segment 320 is less than a width of the second isolation segment 330.

The display panel 10 provided in the embodiments of the present application includes the baseplate 100, the isolation structure 300 and the sub-pixel 400. The isolation structure 300 is disposed on the side of the baseplate 100 and enclosed to form the first opening regions 311, the sub-pixel 400 is at least partially located in the first opening region 311, and the isolation structure 300 can be used for dividing the sub-pixels 400 of the display panel 10. The width of the first isolation segment 320 is less than the width of the second isolation segment 330 so that in the thickness direction X of the display panel 10, the first isolation segment 320 on the periphery of the first opening region 311 is not easy to cause a relatively large blocking effect on light and the light can better penetrate the display panel 10, thereby better improving the light transmission of the display panel 10.

Optionally, embodiments in the first aspect of the present application further provide a display panel 10 that may be the display panel 10 in any one of the preceding embodiments. Therefore, the display panel 10 further provided in the embodiments of the present application may have the beneficial effects of the display panel 10 in any one of the preceding embodiments, and the beneficial effects are not repeated in the present application.

For example, the isolation structure 300 may be the isolation structure 300 in any one of the preceding embodiments, the first isolation segment 320 and the second isolation segment 330 can enclose to form the second opening region 312 in any one of the preceding embodiments, the isolation structure 300 may include the first isolation portion 301, the second isolation portion 302 and the third isolation portion 303 in any one of the preceding embodiments, and when the light-emitting unit 420 and the second electrode 430 of the sub-pixel 400 are prepared, the isolation structure 300 can be used for separating the materials of the light-emitting unit 420 and the second electrode 430. For example, the sub-pixel 400 may be the sub-pixel 400 in any one of the preceding embodiments and may include the first type of sub-pixel 400a, the second type of sub-pixel 400b and the third type of sub-pixel 400c of different emitted colors. For example, the baseplate 100 may be the baseplate 100 in any one of the preceding embodiments, the first electrode 410 in the sub-pixel 400 can be connected to the transistor 151 in the baseplate 100 via the connecting hole 161, and for the arrangement manner of the connecting hole 161, reference may be made to the arrangement manner of the connecting hole 161 in any one of the preceding embodiments.

Optionally, the display panel 10 may further include the pixel defining portion 200 in any one of the preceding embodiments, the pixel defining portion 200 can enclose to form the pixel openings 210 in any one of the embodiments, and for the arrangement manners of the second opening regions 312, the first isolation segment 320 and the pixel openings 210, reference may be made to the arrangement manners of the second opening regions 312, the first isolation segment 320 and the pixel openings 210 in any one of the preceding embodiments.

Optionally, the display panel 10 may further include the encapsulation layer 500 and the touch electrode 600 in any one of the preceding embodiments, and for the arrangement position of the touch electrode 600, reference may be made to the arrangement position of the touch electrode 600 in any one of the preceding embodiments.

It is to be noted that for the composition and material of the isolation structure (also known as the partition structure), reference may be made to related technical solutions recorded in patents or patent applications PCT/CN2023/134518, 202310771071.0, 202311117143.6, 202310759370.2, 202311499823.9, 202311764506.5, 202310707209.0, 202311346196.5, 202310692671.8 and 202310909421.5.

Embodiments in a second aspect of the present application provide a display device. The display device includes the display panel 10 in any one of the preceding embodiments. The display device provided in the embodiments in the second aspect of the present application includes the display panel 10 in any one of the preceding embodiments in the first aspect. Therefore, the display device provided in the embodiments in the second aspect of the present application has the beneficial effects of the display panel 10 in any one of the preceding embodiments in the first aspect, and the details are not repeated here.

Optionally, a photosensitive module is disposed in correspondence to at least one second opening region 312 so that the photosensitive module can acquire light information via the second opening region 312.

The display device in the embodiment of the present application includes but is not limited to devices with display functions, such as a mobile phone, a personal digital assistant (PDA), a tablet computer, an e-book, a television, an access control, an intelligent fixed-line telephone, and a console.

Optionally, the display device may include a photosensitive assembly disposed on a side of the display panel 10 for sensing light, and the light can better pass through the display panel 10 with relatively good light transmission to be sensed by the photosensitive assembly.

Optionally, multiple types of photosensitive assemblies are disposed. For example, the photosensitive assembly may include at least one of the assemblies that can sense light such as a distance sensor, a camera, an under-screen fingerprint recognition module and an infrared light-emitting diode proximity sensor.

According to embodiments of the present application as described above, these embodiments do not describe all details, nor do they limit the present disclosure to only the specific embodiments described. Apparently, many modifications and variations are possible in light of the preceding description. These embodiments have been chosen and described in detail in the specification in order to better explain the principle and practical application of the present application, thereby enabling those skilled in the art to make better use of the present application and its modifications. The present application is limited only by the claims and their full scope and equivalents.

What is claimed is:

1. A display panel, comprising:
a baseplate;
an isolation structure layer disposed on a side of the baseplate and comprising an isolation structure and a plurality of first defining openings formed by enclosure of the isolation structure, wherein the isolation structure comprises an isolation portion located between two adjacent first defining openings among the plurality of first defining openings, wherein the isolation portion comprises a light-shielding portion; and
a light-emitting functional layer comprising at least one first electrode, at least one light-emitting unit and at least one second electrode, wherein a light-emitting unit and a second electrode are at least partially located in a first defining opening and are sequentially stacked in a direction facing away from the baseplate, and a plurality of sub-pixels are formed by at least a portion of the at least one first electrode, a portion of the at least one light-emitting unit and a portion of the at least one second electrode;
wherein at least one first defining opening among the plurality of first defining openings comprises at least one first opening region and at least one second opening region, wherein an orthographic projection of a first electrode on the baseplate coincides with an orthographic projection of a first opening region on the baseplate, a light-transmissive gap is formed between the orthographic projection of the first electrode on the baseplate and an orthographic projection of an edge of the light-shielding portion of the isolation portion on the baseplate, and an orthographic projection of a second opening region on the baseplate is located within an orthographic projection of the light-transmissive gap on the baseplate.

2. The display panel according to claim 1, wherein the light-emitting unit is provided with at least one second hollowed-out opening passing through the light-emitting unit, and an orthographic projection of a second hollowed-out opening on the baseplate at least partially overlaps the orthographic projection of the light-transmissive gap on the baseplate; or
the second electrode is provided with at least one third hollowed-out opening passing through the second electrode, and an orthographic projection of a third hollowed-out opening on the baseplate at least partially overlaps the orthographic projection of the light-transmissive gap on the baseplate.

3. The display panel according to claim 1, further comprising at least one connection portion, wherein a connection portion among the at least one connection portion is connected to the first electrode;
the baseplate comprises at least one driver circuit and a planarization layer disposed on a side of the at least one driver circuit facing the sub-pixel, wherein at least one connecting hole is disposed on the planarization layer, and the connection portion is connected to a driver circuit via a connecting hole; and
a material of the connection portion comprises a light-transmissive material, wherein an orthographic projection of the connection portion on the baseplate is at least partially located within the orthographic projection of the second opening region on the baseplate, or an orthographic projection of the connection portion on the baseplate is located outside the orthographic projection of the second opening region on the baseplate.

4. The display panel according to claim 3, wherein the light-emitting functional layer further comprises a second conductive layer, wherein the second conductive layer is located on a side of the at least one first electrode facing or facing away from the baseplate and is in contact with the at least one first electrode, a transmittance of the second conductive layer is greater than a transmittance of the at least one first electrode, and the at least one connection portion and the second conductive layer are disposed in a same layer and are made of a same material; and
the orthographic projection of the at least one second opening region on the baseplate at least partially overlaps an orthographic projection of the second conductive layer on the baseplate.

5. The display panel according to claim 3, wherein the display panel comprises a first display region and a second display region, wherein a transmittance of the first display region is greater than a transmittance of the second display region, the at least one driver circuit is located in the second display region, the first electrode connected to the connection portion is located in the first display region, the material of the connection portion comprises the light-transmissive material, and the connection portion extends from the first display region to the second display region.

6. The display panel according to claim 1, further comprising a pixel defining layer, wherein the pixel defining layer comprises a pixel defining portion and a plurality of pixel openings formed by enclosure of the pixel defining portion, the isolation structure is disposed on a side of the pixel defining portion facing away from the baseplate, a pixel opening among the plurality of pixel openings is communicated with the first defining opening, and the light-emitting unit is at least partially located in the pixel opening;
a material of the pixel defining portion comprises a light-transmissive material; or
at least one defining layer opening is disposed on the pixel defining portion, an orthographic projection of a defining layer opening on the baseplate at least partially overlaps the orthographic projection of the second opening region on the baseplate, and the defining layer opening is communicated with the pixel opening, or the defining layer opening and the pixel opening are spaced apart from each other.

7. The display panel according to claim 1, further comprising:
a light-filtering layer located on a side of the light-emitting functional layer facing away from the baseplate; wherein the light-filtering layer comprises a light-shielding defining portion, a plurality of second defining openings formed by enclosure of the light-shielding defining portion, and a plurality of light-filtering units, and a light-filtering unit among the plurality of light-filtering units is at least partially located at a second defining opening;
wherein the plurality of second defining openings comprise at least one third opening region and at least one fourth opening region, wherein an orthographic projection of a fourth opening region on the baseplate at least partially overlaps the orthographic projection of a second opening region on the baseplate, and the light-filtering unit is located in a third opening region.

8. The display panel according to claim 1, wherein a driver circuit layer is disposed on the baseplate and comprises at least one light-transmissive structure, wherein an orthographic projection of a light-transmissive structure on the baseplate at least partially overlaps an orthographic projection of a second opening region on the baseplate;
the driver circuit layer comprises a plurality of conductive functional portions, wherein an orthographic projection of a conductive functional portion on the baseplate is located outside an orthographic projection of a second opening region on the baseplate; and
the plurality of conductive functional portions are light-proof, wherein the at least one light-transmissive structure is formed by a gap between different conductive functional portions among the plurality of conductive functional portions.

9. The display panel according to claim 1, wherein the isolation structure comprises a first isolation portion and a second isolation portion that are stacked in a direction away from the baseplate, wherein the second isolation portion protrudes from the first isolation portion toward the plurality of first defining openings; and
a material of the second isolation portion is a light-transmissive material, and the light-shielding portion comprises the first isolation portion.

10. The display panel according to claim 1, wherein the isolation structure comprises a third isolation portion, a first isolation portion and a second isolation portion that are stacked in a direction facing away from the baseplate, wherein the second isolation portion and the third isolation portion protrude from the first isolation portion toward the plurality of first defining openings; and
a material of the second isolation portion comprises a light-transmissive material, and the light-shielding portion comprises the third isolation portion.

11. The display panel according to claim 1, wherein the plurality of first defining openings comprise at least one first type of defining opening, at least one second type of defining opening, and at least one third type of defining opening; the plurality of sub-pixels comprise at least one first type of sub-pixel corresponding to the at least one first type of defining opening, at least one second type of sub-pixel corresponding to the at least one second type of defining opening and at least one third type of sub-pixel corresponding to the at least one third type of defining opening; and
at least one of the at least one first type of defining opening, the at least one second type of defining opening and the at least one third type of defining opening comprises a first opening region and a second opening region, wherein one second opening region is disposed on a periphery of a first opening region, or more than two second opening regions are distributed on a periphery of a first opening region at intervals.

12. The display panel according to claim 11, wherein the at least one first type of sub-pixel and the at least one third type of sub-pixel are alternately arranged along a first direction to form a first pixel row, a plurality of second type of sub-pixels are arranged along the first direction in sequence to form a second pixel row, and the first pixel row and the second pixel row are alternately arranged along a second direction;
the at least one first type of sub-pixel and the at least one third type of sub-pixel are alternately arranged along the second direction to form a first pixel column, and the plurality of second type of sub-pixels are arranged along the second direction in sequence to form a second pixel column; and
a second opening region is located between a first type of sub-pixel and a third type of sub-pixel that are adjacent along the first direction or the second direction.

13. The display panel according to claim 12, wherein an area of an orthographic projection of a second type of sub-pixel on the baseplate is less than an area of an orthographic projection of a first type of sub-pixel on the baseplate;
the area of the orthographic projection of the second type of sub-pixel on the baseplate is less than an area of an orthographic projection of a third type of sub-pixel on the baseplate;
each of a first type of defining opening and a third type of defining opening comprises at least one first opening region and at least one second opening region; and
a portion of second opening regions are disposed in the at least one first type of defining opening, and another portion of the second opening regions are disposed in the at least one third type of defining opening.

14. The display panel according to claim 13, wherein a plurality of second opening regions are disposed on a periphery of a first opening region of a first type of defining opening at intervals;
two second opening regions are located on two sides of the first opening region of the first type of defining opening in the first direction, or two second opening regions are located on two sides of the first opening region of the first type of defining opening in the second direction;
each of a side of the first opening region of the first type of defining opening in the first direction and a side of the first opening region of the first type of defining opening in the second direction is provided with at least one second opening region;
a plurality of second opening regions are disposed on a periphery of a first opening region of a third type of defining opening at intervals;
two second opening regions are located on two sides of the first opening region of the third type of defining opening in the first direction, or two second opening regions are located on two sides of the first opening region of the third type of defining opening in the second direction; and
each of a side of the first opening region of the third type of defining opening in the first direction and a side of the first opening region of the third type of defining opening in the second direction is provided with at least one second opening region.

15. The display panel according to claim 12, wherein
a second type of defining opening comprises at least one first opening region and at least one second opening region; and
at least one second opening region is disposed in a second type of defining opening and is located on at least one side of a first opening region of the second type of defining opening in the first direction or the second direction.

16. The display panel according to claim 15, wherein
at least one second opening region is disposed in the second type of defining opening and is located on at least one side of a first opening region of the second type of defining opening in the second direction, and at least one second opening region is disposed in the first type of defining opening and is located on at least one side of a first opening region of the first type of defining opening in the second direction;
a third type of defining opening comprises at least one first opening region and at least one second opening region, wherein at least one second opening region is disposed in the third type of defining opening and is located on at least one side of a first opening region of the third type of defining opening in the second direction;
two second opening regions are located on two sides of the first opening region of the first type of defining opening in the second direction;
a second opening region comprises a first type of light-transmissive region located between a first type of sub-pixel and a third type of sub-pixel that are adjacent along the first direction, wherein the first type of light-transmissive region is disposed in a second type of defining opening; and
a second opening region comprises a second type of light-transmissive region located between a first type of sub-pixel and a second type of sub-pixel that are adjacent along the second direction, wherein the second type of light-transmissive region is disposed in a first type of defining opening or the third type of defining opening.

17. The display panel according to claim 15, wherein second opening regions are disposed on two sides of a first opening region of the second type of defining opening in the first direction and two sides of the first opening region of the second type of defining opening in the second direction.

18. The display panel according to claim 1, further comprising a touch electrode disposed on a side of the isolation structure facing away from the baseplate, and an orthographic projection of the touch electrode on the baseplate is located within an orthographic projection of the isolation structure on the baseplate.

19. A display panel, comprising:
a baseplate;
an isolation structure disposed on a side of the baseplate and enclosing to form at least one first opening region; and
at least one sub-pixel, a sub-pixel of the at least one sub-pixel is at least partially located in a first opening region of the at least one first opening region;
wherein at least one second opening region communicated with a first opening region is disposed on a side of at least a portion of the isolation structure facing an isolation opening, and the at least one second opening region passes through the isolation structure along a thickness direction of the display panel.

20. The display panel according to claim 19, further comprising a pixel defining portion, wherein the pixel defining portion encloses to form a plurality of pixel openings, and a sub-pixel is partially located in a pixel opening among the plurality of pixel openings;
a material of the pixel defining portion comprises a light-transmissive material, wherein an orthographic projection of the second opening region on the baseplate at least partially overlaps an orthographic projection of the pixel defining portion on the baseplate;
the pixel opening is connected to the first opening region;
the pixel opening comprises at least one first opening, at least one second opening and at least one third opening, wherein a first spacing is set between adjacent first and third openings, a second spacing is set between adjacent first and second openings, the first spacing is greater than the second spacing, and a second opening region is located between a first opening and a third opening; and
the at least one first opening and the at least one third opening are alternately arranged along a first direction to form a first pixel column, and a plurality of second openings are arranged along the first direction at intervals to form a second pixel column, a second opening region is located between adjacent first and third openings in the first pixel column, the first pixel column and the second pixel column are alternately arranged in the second direction, and the first direction intersects the second direction; or the at least one first opening and the at least one third opening are alternately arranged along a second direction to form a first pixel row, and a plurality of second openings are arranged along the second direction at intervals to form a second pixel row, a second opening region is located between adjacent first and third openings in the first pixel row, the first pixel row and the second pixel row are alternately arranged in the first direction, and the first direction intersects the second direction.

21. The display panel according to claim 19, wherein
the isolation structure comprises a first isolation segment and a second isolation segment that are connected to each other, wherein a width of the first isolation segment is less than a width of the second isolation segment, and the first isolation segment is located on a side of the second opening region;
a second electrode is lapped with a first isolation portion and a second isolation portion; or a second electrode is lapped with a second isolation portion and is spaced apart from a first isolation portion, a third hollowed-out opening passes through the second electrode, and an orthographic projection of the third hollowed-out opening on the baseplate at least partially overlaps an orthographic projection of a light-transmissive gap on the baseplate;
the first isolation segment is connected between two adjacent second isolation segments, and the second opening region is located between the adjacent second isolation segments;
a plurality of isolation openings are provided, and the second opening region is located on at least one side of the first isolation segment facing the plurality of isolation openings;
second opening regions are disposed on two sides of the first isolation segment, and the first isolation segment is centrally arranged relative to the two second opening regions located on the two sides of the first isolation segment; and
the display panel further comprises a pixel defining portion, wherein the pixel defining portion encloses to form a plurality of pixel openings, the sub-pixel is partially located in the pixel opening, and a minimum spacing between an orthographic projection of the first isolation segment on the baseplate and an orthographic projection of the pixel opening on the baseplate is greater than a minimum spacing between an orthographic projection of the second isolation segment on the baseplate and the orthographic projection of the pixel opening on the baseplate.

22. The display panel according to claim 19, further comprising a touch electrode disposed on a side of the isolation structure facing away from the baseplate, and an orthographic projection of the touch electrode on the baseplate is located within an orthographic projection of the isolation structure on the baseplate.

23. A display device, comprising:
the display panel according to claim 1; and
a photosensitive module disposed in correspondence to the at least one second opening region.
